(19) United States
(12) Patent Application Publication
(10) Pub. No.: US 2014/0239263 A1
(43) Pub. Date: Aug. 28, 2014

(54) ANTHRACENE-BASED COMPOUND AND ORGANIC LIGHT EMITTING DIODE COMPRISING THE SAME

(71) Applicant: Samsung Display Co., Ltd., Yongin-City (KR)

(72) Inventors: Hee-Yeon Kim, Yongin-City (KR); Seung-Gak Yang, Yongin-City (KR)

(73) Assignee: Samsung Display Co., Ltd., Yongin-City (KR)

(21) Appl. No.: 13/949,139

(22) Filed: Jul. 23, 2013

(30) Foreign Application Priority Data
Feb. 25, 2013 (KR) 10-2013-0020016

(51) Int. Cl. H01L 51/00

(52) U.S. Cl. CPC H01L 51/0072; H01L 51/0058; H01L 51/0055
USPC 257/40; 546/121

(57) ABSTRACT

An anthracene-based compound and an organic light emitting diode comprising the anthracene-based compound have been disclosed.

### CROSS-REFERENCE TO RELATED APPLICATION

This application claims priority to and the benefit of Korean Patent Application No. 10-2013-0020016, filed on Feb. 25, 2013, in the Korean Intellectual Property Office, the entire content of which is incorporated herein by reference.

### BACKGROUND

1. Field

The following description relates to a compound for organic light-emitting diodes and an organic light-emitting diode.

2. Description of the Related Art

Organic light-emitting diodes (OLEDs), which are self-emitting diodes, have advantages such as wide viewing angles, excellent contrast, quick response, high brightness, excellent driving voltage characteristics, and can provide multicolored images.

A typical OLED has a structure including a substrate, and an anode, a hole transport layer (HTL), an emission layer (EML), an electron transport layer (ETL), and a cathode which are sequentially stacked on the substrate. In this regard, the HTL, the EML, and the ETL are organic thin films formed of organic compounds.

An operating principle of an OLED having the above-described structure is as follows.

When a voltage is applied between the anode and the cathode, holes injected from the anode move to the EML via the HTL, and electrons injected from the cathode move to the EML via the ETL. The holes and electrons recombine in the EML to generate excitons. When the excitons drop from an excited state to a ground state, light is emitted.

### SUMMARY

Aspects of embodiments of the present disclosure are directed toward an anthracene-based compound having a new structure and an organic light emitting diode including the anthracene-based compound.

According to an embodiment of the present disclosure, there is provided an anthracene-based compound represented by Formula 1 below:

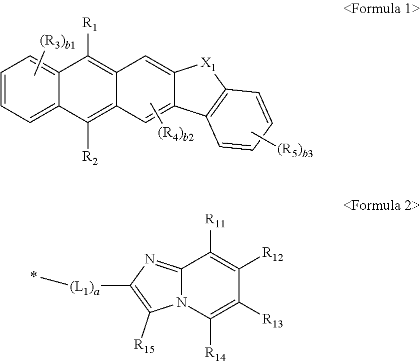

In Formulae 1 and 2,

X₁ is C(R₆)(R₇) or N(R₈);

R₁ to R₈ and R₁₁ to R₁₅ are, each independently, selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, —N(Q₁)(Q₂), —Si(Q₃)(Q₄)(Q₅) (wherein, Q₁ to Q₅ are, each independently, a hydrogen atom, a substituted or unsubstituted C₁-C₆₀ alkyl group, a substituted or unsubstituted C₆-C₆₀ aryl group, or a substituted or unsubstituted C₂-C₆₀ heteroaryl group) and the groups represented by Formula 2 below, wherein at least one of R₁, R₂, 131 number of R₃, b2 number of R₄ and b3 number of R₅ is a group represented by Formula 2;

b1 and b3 are, each independently, an integer of 1 to 4;

b2 is 1 or 2;

L₁ is selected from a substituted or unsubstituted C₃-C₁₀ cycloalkylene group, a substituted or unsubstituted C₂-C₁₀ heterocycloalkylene group, a substituted or unsubstituted C₃-C₁₀ cycloalkenylene group, a substituted or unsubstituted C₂-C₁₀ heterocycloalkenylene group, a substituted or unsubstituted C₆-C₆₀ arylene group, and a substituted or unsubstituted C₂-C₆₀ heteroarylene group;

a is an integer of 0 to 5; and

* in Formula 2 is a binding site to a group represented by Formula 1.

According to another embodiment of the present disclosure, there is provided an organic light-emitting diode including: a first electrode; a second electrode facing the first electrode; and an organic layer disposed between the first electrode and the second electrode and including an emission layer, wherein the organic layer further includes a hole transport region between the first electrode and the emission layer and an electron transport region between the emission layer and the second electrode, wherein the organic layer includes at least one anthracene-based compound.

### BRIEF DESCRIPTION OF THE DRAWINGS

The above and other features and advantages of the present disclosure will become more apparent by describing in more detail embodiments thereof with reference to the attached drawings in which:

FIG. 1 schematically illustrates the structure of an organic light emitting diode according to an embodiment of the present disclosure; and

FIG. 2 is a graph showing a brightness-emission efficiency of an organic light emitting diode manufactured in the Examples and Comparative Examples.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list.

According to an embodiment of the present disclosure, an anthracene-based compound is represented by Formula 1 below:

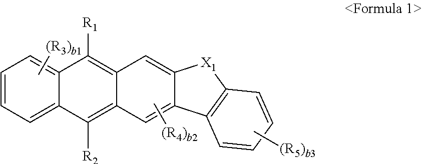

In Formula 1 above, X₁ is C(R₆)(R₇) or N(R₈).

For example, X₁ in Formula 1 is C(R₆)(R₇), but is not limited thereto.

In Formula 1, R₁ to R₅ and R₆ to R₈ (referred to in the description of X₁ of Formula 1), are, each independently, selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, —N(Q₁)(Q₂), —Si(Q₃)(Q₄)(Q₅) (wherein, Q₁ to Q₅ are, each independently, a hydrogen atom, a substituted or unsubstituted C₆-C₆₀ alkyl group, a substituted or unsubstituted C₆-C₆₀ aryl group or a substituted or unsubstituted C₂-C₆₀ heteroaryl group) and a group represented by Formula 2 below, wherein at least one of R₁, R₂, b1 number of R₃, b2 number of R₄ and b3 number of R₅ is a group represented by Formula 2 below.

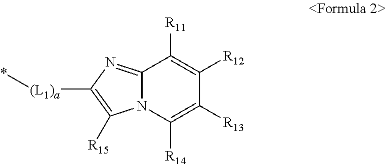

Hence, the anthracene-based compound represented by Formula 1 above includes at least one group represented by Formula 2 above.

b1 represents a number of R₃, and is an integer of 1 to 4. When b1 is 2 or greater, b1 number of R₃ may be the same or different from each other. b2 represents a number of R₄, and is 1 or 2. When b2 is 2, the two R₄ may be the same or different from each other. b3 represents a number of R₅, and is an integer of 1 to 4. When b3 is 2 or greater, b3 number of R₅ may be the same or different from each other.

In Formula 1 above, R₆ to R₈ may be, each independently, selected from,

a C₁-C₂₀ alkyl group;

a C₁-C₂₀ alkyl group substituted with at least one selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, a phenyl group, a naphthyl group, an anthryl group, and a dimethyl fluorenyl group;

a C₆-C₂₀ aryl group; and

a C₆-C₂₀ aryl group substituted with at least one selected from a deuterium atom, a halogen atom, a hydroxyl group, a cyano group, a nitro group, an amino group, an amidino group, a hydrazine, a hydrazone, a carboxyl group or a salt thereof, a C₁-C₂₀ alkyl group, a C₁-C₂₀ alkoxy group, a sulfonic acid group or a salt thereof, a phosphoric acid group or a salt thereof, a phenyl group, a naphthyl group, an anthryl group, and a dimethyl fluorenyl group.

According to an embodiment of the present disclosure, in the Formulae above, R₆ to R₈ are, each independently, selected from,

a methyl group, an ethyl group, a propyl group, a butyl group, a pentyl group, a hexyl group, a heptyl group, and an octyl group;

a methyl group, an ethyl group, a propyl group, a butyl group, a pentyl group, a hexyl group, a heptyl group, and an octyl group, each substituted with at least one substituent selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a phenyl group, a naphthyl group, an anthryl group, and a dimethyl fluorenyl group;

a phenyl group, a naphthyl group, and an anthryl group; and

a phenyl group, a naphthyl group, and an anthryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a C₁-C₂₀ alkyl group, a C₁-C₂₀ alkoxy group, a sulfonic acid group or a salt thereof, a phosphoric acid group or a salt thereof, a phenyl group, a naphthyl group, an anthryl group, and a dimethyl fluorenyl group, but is not limited thereto.

In Formula 1 above, R₁ and R₂ may be, each independently, selected from,

a C₆-C₆₀ aryl group, and a C₂-C₆₀ heteroaryl group; and

a C₆-C₆₀ aryl group, and a C₂-C₆₀ heteroaryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a C₁-C₂₀ alkyl group, a C₁-C₂₀ alkoxy group, a sulfonic acid group or a salt thereof, a phosphoric acid group or a salt thereof, a phenyl group, a naphthyl group, an anthryl group, and a dimethyl fluorenyl group.

For example, in Formula 1 above, R₁ and R₂ are, each independently, selected from,

a phenyl group, a pentalenyl group, an indenyl group, a naphthyl group, an azulenyl group, a heptalenyl group, an indacenyl group, an acenaphthyl group, a fluorenyl group, a Spiro-fluorenyl group, a phenalenyl group, a phenanthrenyl group, an anthryl group, a fluoranthenyl group, a triphenylenylene group, a pyrenyl group, a chrysenyl group, a naphthacenyl group, a picenyl group, a perylenyl group, a pentaphenyl group, and a hexacenyl group; and

a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthryl group, a fluoranthenyl group, a triphenylenylene group, a pyrenyl group, a chrysenyl group, a naphthacenyl group, a picenyl group, a perylenyl group, a pentaphenyl group, and a hexacenyl group, each substituted with at least one of a deuterium atom, a halogen atom, a hydroxyl group, a cyano group, a nitro group, an amino group, an amidino group, a hydrazine, a hydrazone, a carboxyl group or a salt thereof, C₁-C₂₀ alkyl group, C₁-C₂₀ alkoxy group, a sulfonic acid group or a salt thereof, a phosphoric acid group or a salt thereof, a phenyl group, a naphthyl group, an anthryl group, and a dimethyl fluorenyl group.

According to another embodiment of the present disclosure, in Formula 1, R₁ and R₂ may be, each independently, selected from,

a phenyl group, a naphthyl group, a fluorenyl group, and a spiro-fluorenyl group; and

a phenyl group, a naphthyl group, a fluorenyl group, and a spiro-fluorenyl group, each substituted with a deuterium atom, a halogen atom, a hydroxyl group, a cyano group, a nitro group, an amino group, an amidino group, a hydrazine, a hydrazone, a carboxyl group or a salt thereof, C₁-C₂₀ alkyl group, C₁-C₂₀ alkoxy group, a sulfonic acid group or a salt thereof, a phosphoric acid group or a salt thereof, a phenyl group, a naphthyl group, an anthryl group, and a dimethyl fluorenyl group, but are not limited thereto.

In Formula 1 above, R₃ to R₅ may be, each independently, selected from

a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group;

a C₁-C₆₀ alkyl group, and a C₁-C₆₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

a C₆-C₂₀ aryl group;

a C₆-C₂₀ aryl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, a C₁-C₆₀ alkyl group, a C₁-C₆₀ alkoxy group, a phenyl group, a naphthyl group, and an anthryl group; and

a group represented by Formula 2 above;

wherein, at least one of b1 number of R₃, b2 number of R₄ and b3 number of R₅ may be a group represented by Formula 2 above.

For example, in Formula 1 above, R₃ to R₅ are, each independently, selected from,

a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group;

a C₁-C₆₀ alkyl group, and a C₁-C₆₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

a phenyl group, a naphthyl group, and an anthryl group;

a phenyl group, a naphthyl group, and an anthryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, a C₁-C₆₀ alkyl group, a C₁-C₆₀ alkoxy group, a phenyl group, a naphthyl group, and an anthryl group; and

a group represented by Formula 2 above;

wherein, at least one of b1 number of R₃, b2 number of R₄ and b3 number of R₅ is a group represented by Formula 2 above.

According to an embodiment of the present disclosure, in Formula 1 above, at least one of b3 number of R₅ is a group represented by Formula 2 above.

According to another embodiment of the present disclosure, in Formula 1 above, at least one of b3 number of R₅ and at least one of b1 number of R₃ is a group represented by Formula 2 above.

According to another embodiment of the present disclosure, in Formula 1 above, at least one of b3 number of R₅ or at least one of b1 number of R₃ is a group represented by Formula 2 above.

In Formula 2 above, L₁ is selected from a substituted or unsubstituted C₃-C₁₀ cycloalkylene group, a substituted or unsubstituted C₂-C₁₀ heterocycloalkylene group, a substituted or unsubstituted C₃-C₁₀ cycloalkenylene group, a substituted or unsubstituted C₂-C₁₀ heterocycloalkenylene group, a substituted or unsubstituted C₆-C₆₀ arylene group, and a substituted or unsubstituted C₂-C₆₀ heteroarylene group.

For example, in Formula 1 above, L₁ is selected from,

i) a phenylene group, a pentalenylene group, an indenylene group, a naphthylene group, an azulenylene group, a heptalenylene group, an indacenylene group, an acenaphthylene group, a fluorenylene group, a spirofluorenylene group, a phenalenylene group, a phenanthrenylene group, an anthrylene group, a fluoranthenylene group, a triphenylenylene group, a pyrenylene group, a chrysenylene group, a naphthacenylene group, a picenylene group, a perylenylene group, pentaphenylene group, a hexacenylene group, a pyrrolylene group, an imidazolylene group, a pyrazolylene group, a pyridinylene group, a pyrazinylene group, a pyrimidinylene group, a pyridazinylene group, an isoindolylene group, an indolylene group, an indazolylene group, a purinylene group, a quinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzooxazolylene group, a benzoimidazolylene group, a furanylene group, a benzofuranylene group, a thiophenylene group, a benzothiophenylene group, a thiazolylene group, an isothiazolylene group, a benzothiazolylene group, an isoxazolylene group, an oxazolylene group, a triazolylene group, a tetrazolylene group, an oxadiazolylene group, a triazinylene group, a benzooxazolylene group, a dibenzofuranylene group, a dibenzothiophenylene group, and a benzocarbazolylene group; and

ii) a phenylene group, a pentalenylene group, an indenylene group, a naphthylene group, an azulenylene group, a heptalenylene group, an indacenylene group, an acenaphthylene group, a fluorenylene group, a spirofluorenylene group, a phenalenylene group, a phenanthrenylene group, an anthrylene group, a fluoranthenylene group, a triphenylenylene group, a pyrenylene group, a chrysenylene group, a naphthacenylene group, a picenylene group, a perylenylene group, pentaphenylene group, a hexacenylene group, a pyrrolylene group, an imidazolylene group, a pyrazolylene group, a pyridinylene group, a pyrazinylene group, a pyrimidinylene group, a pyridazinylene group, an isoindolylene group, an indolylene group, an indazolylene group, a purinylene group, a quinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzooxazolylene group, a benzoimidazolylene group, a furanylene group, a benzofuranylene group, a thiophenylene group, a benzothiophenylene group, a thiazolylene group, an isothiazolylene group, a benzothiazolylene group, an isoxazolylene group, an oxazolylene group, a triazolylene group, a tetrazolylene group, an oxadiazolylene group, a triazinylene group, a benzooxazolylene group, a dibenzofuranylene group, a dibenzothiophenylene group, and a benzocarbazolylene group, each substituted with at least one of,

a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, C₁-C₂₀ alkyl group, and C₁-C₂₀ alkoxy group;

a C₁-C₂₀ alkyl group, and C₁-C₂₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

a C₆-C₂₀ aryl group, and a C₂-C₂₀ heteroaryl group; and

a C₆-C₂₀ aryl group, and a C₂-C₂₀ heteroaryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthryl group, a fluorenyl group, a dimethyl fluorenyl group, a diphenyl fluorenyl group, a carbazolyl group, a phenyl carbazolyl group, a pyridinyl group, a pyrimidinyl group, a pyrazinyl group, a pyridazinyl group, a triazinyl group, a quinolinyl group, and an isoquinolinyl group.

For example, in Formula 2, L₁ is selected from,

a phenylene group, a naphthylene group, and an anthrylene group; and

a phenylene group, a naphthylene group, and an anthrylene group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group, but is not limited thereto.

In Formula 2, a represents a number of L₁, and may be an integer of 1 to 5. When a is 2 or greater, a number of L₁ may be the same or different from each other. For example, a is 1 or 2, but is not limited thereto.

In Formula 2, R₁₁ to R₁₅ are, each independently, selected from, a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₅₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, —N(Q₁)(Q₂) and —Si(Q₃)(Q₄)(Q₅) (wherein, Q₁ to Q₅ are, each independently, a hydrogen atom, a substituted or unsubstituted C₁-C₆₀ alkyl group, a substituted or unsubstituted C₆-C₆₀ aryl group or a substituted or unsubstituted C₂-C₆₀ heteroaryl group).

In Formula 2, R₁₁ to R₁₅ may be, each independently, selected from,

a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group;

a C₁-C₆₀ alkyl group, and a C₁-C₆₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

a C₆-C₂₀ aryl group; and

a C₆-C₂₀ aryl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, C₁-C₆© alkyl group, C₁-C₆₀ alkoxy group, a phenyl group, a naphthyl group, and an anthryl group.

According to an embodiment of the present disclosure, R₁₁ to R₁₅ may be, each independently, selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a propyl group, a butyl group, a pentyl group, a hexyl group, a heptyl group, an octyl group, a methoxy group, an ethoxy group, a propoxy group, a butoxy group, a pentoxy group, a phenyl group, a naphthyl group, an anthryl group, a dimethyl fluorenyl group, and a phenyl carbazolyl group.

For example, the anthracene-based compound is represented by Formula 1A or 1B below:

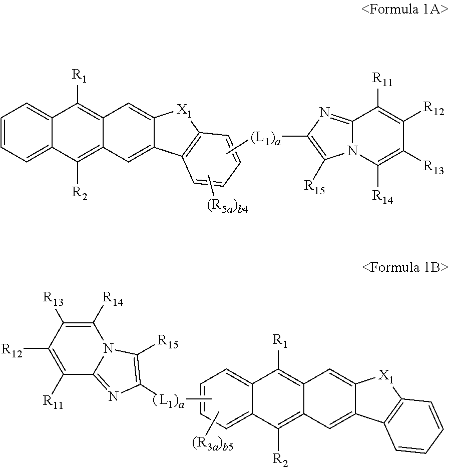

In Formula 1A and 1B, R₁, R₂, X₁, L₁, R¹¹ to R₁₅, and a are as defined above, R₅ₐ is as defined in R₅, and b4 is an integer of 1 to 3.

For example, in Formulae 1A and 1B,

i) X₁ is C(R₆)(R₇) or N(R₈);

ii) R₆ to R₈ are, each independently, selected from,

a methyl group, an ethyl group, a propyl group, a butyl group, a pentyl group, a hexyl group, a heptyl group, and an octyl group;

a methyl group, an ethyl group, a propyl group, a butyl group, a pentyl group, a hexyl group, a heptyl group, and an octyl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a phenyl group, a naphthyl group, an anthryl group, and a dimethyl fluorenyl group;

a phenyl group, a naphthyl group, and an anthryl group; and

a phenyl group, a naphthyl group, and an anthryl group, each substituted with at least one of a deuterium atom, a halogen atom, a hydroxyl group, a cyano group, a nitro group, an amino group, an amidino group, a hydrazine, a hydrazone, a carboxyl group or a salt thereof, C₁-C₂₀ alkyl group, C₁-C₂₀ alkoxy group, a sulfonic acid group or a salt thereof, a phosphoric acid group or a salt thereof, a phenyl group, a naphthyl group, an anthryl group, and a dimethyl fluorenyl group;

iii) R₁ and R₂ are, each independently, selected from, a phenyl group, a naphthyl group, a fluorenyl group, and a spiro-fluorenyl group; a phenyl group, a naphthyl group, a fluorenyl group, and a spiro-fluorenyl group, each substituted with at least one of and a deuterium atom, a halogen atom, a hydroxyl group, a cyano group, a nitro group, an amino group, an amidino group, a hydrazine, a hydrazone, a carboxyl group or a salt thereof, C₁-C₂₀ alkyl group, C₁-C₂₀ alkoxy group, a sulfonic acid group or a salt thereof, a phosphoric acid group or a salt thereof, a phenyl group, a naphthyl group, an anthryl group, and a dimethyl fluorenyl group;

iv) R₅ₐ and R₃ₐ are, each independently,

a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group;

a C₁-C₆₀ alkyl group, and a C₁-C₆₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

a phenyl group, a naphthyl group, and an anthryl group; and

a phenyl group, a naphthyl group, and an anthryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, a C₁-C₆₀ alkyl group, a C₁-C₂₀ alkoxy group, a phenyl group, a naphthyl group, and an anthryl group;

v) b4 and b5 are, each independently, an integer of 1 to 3;

vi) L₁ is selected from a phenylene group, a naphthylene group, and an anthrylene group; and a phenylene group, a naphthylene group, and an anthrylene group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group;

vii) a is 1 or 2;

viii) R₁₁ to R₁₅ are, each independently, selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a propyl group, a butyl group, a pentyl group, a hexyl group, a heptyl group, an octyl group, a methoxy group, an ethoxy group, a propoxy group, a butoxy group, a pentoxy group, a phenyl group, a naphthyl group, an anthryl group, a dimethyl fluorenyl group, and a phenyl carbazolyl group.

According to another embodiment of the present disclosure, the anthracene-based compound is represented by Formula 1A(1) or Formula 1B(1):

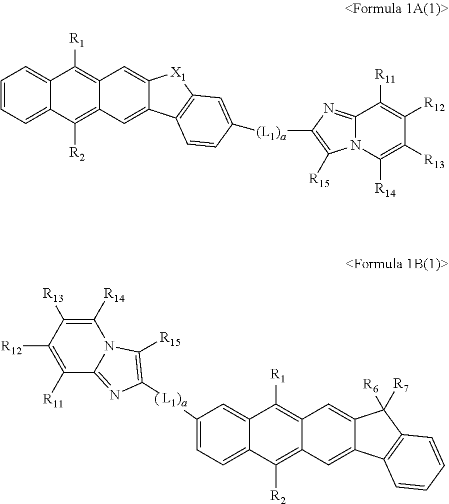

in Formula 1A(1) and 1B(1), R₁, R₂, R₆, R₇, L₁, a and R₁₁ to R₁₅ are as defined in Formula 1A and 1B, respectively.

According to an embodiment of the present disclosure, the anthracene-based compound is one of Compounds 1 to 24 below, but is not limited thereto:

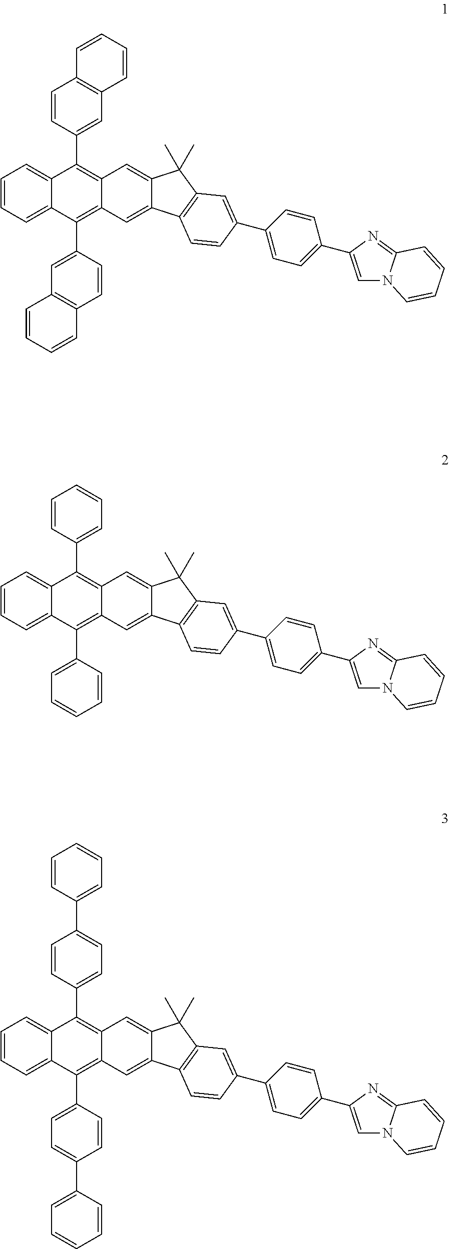 [SMILES: CC1(C)c2cc(-c3ccc(-c4cn5ccccc5n4)cc3)ccc2-c2cc3c(-c4ccc5ccccc5c4)c4ccccc4c(-c4ccc5ccccc5c4)c3cc21 ; CC1(C)c2cc(-c3ccc(-c4cn5ccccc5n4)cc3)ccc2-c2cc3c(-c4ccccc4)c4ccccc4c(-c4ccccc4)c3cc21 ; CC1(C)c2cc(-c3ccc(-c4cn5ccccc5n4)cc3)ccc2-c2cc3c(-c4ccc(-c5ccccc5)cc4)c4ccccc4c(-c4ccc(-c5ccccc5)cc4)c3cc21]

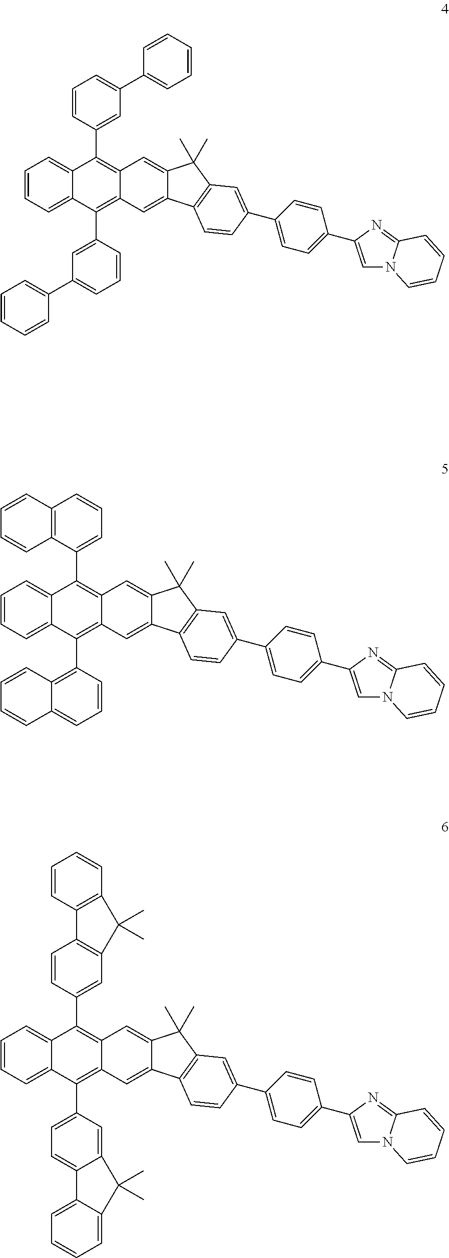 [SMILES: CC1(C)c2cc(-c3ccc(-c4cn5ccccc5n4)cc3)ccc2-c2cc3c(-c4cccc(-c5ccccc5)c4)c4ccccc4c(-c4cccc(-c5ccccc5)c4)c3cc21 ; CC1(C)c2cc(-c3ccc(-c4cn5ccccc5n4)cc3)ccc2-c2cc3c(-c4cccc5ccccc45)c4ccccc4c(-c4cccc5ccccc45)c3cc21 ; CC1(C)c2ccccc2-c2ccc(-c3c4ccccc4c(-c4ccc5c(c4)C(C)(C)c4ccccc4-5)c4cc5c(cc34)-c3ccc(-c4ccc(-c6cn7ccccc7n6)cc4)cc3C5(C)C)cc21]

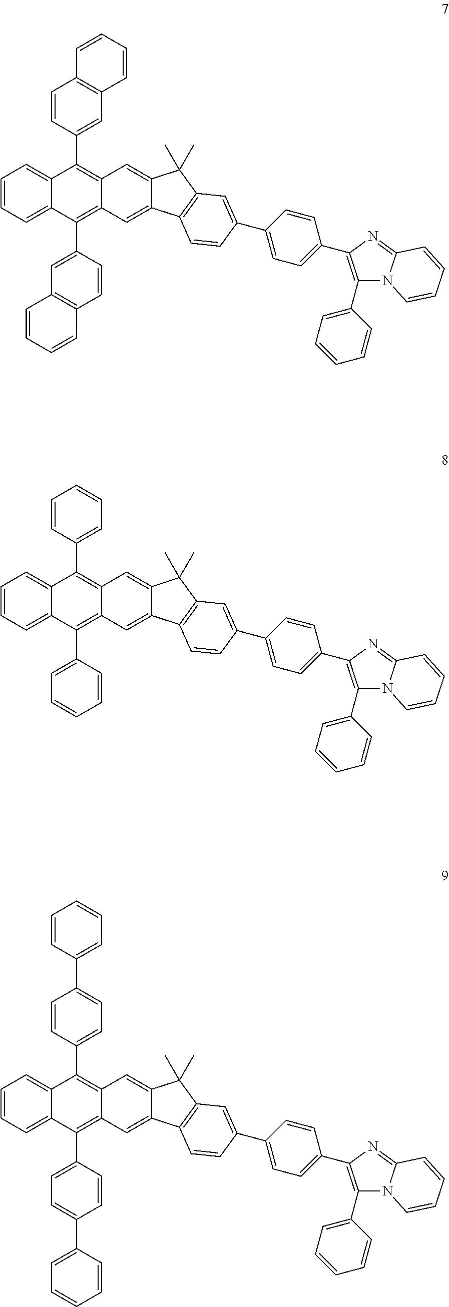 [SMILES: CC1(C)c2cc(-c3ccc(-c4nc5ccccn5c4-c4ccccc4)cc3)ccc2-c2cc3c(-c4ccc5ccccc5c4)c4ccccc4c(-c4ccc5ccccc5c4)c3cc21 ; CC1(C)c2cc(-c3ccc(-c4nc5ccccn5c4-c4ccccc4)cc3)ccc2-c2cc3c(-c4ccccc4)c4ccccc4c(-c4ccccc4)c3cc21 ; CC1(C)c2cc(-c3ccc(-c4nc5ccccn5c4-c4ccccc4)cc3)ccc2-c2cc3c(-c4ccc(-c5ccccc5)cc4)c4ccccc4c(-c4ccc(-c5ccccc5)cc4)c3cc21]

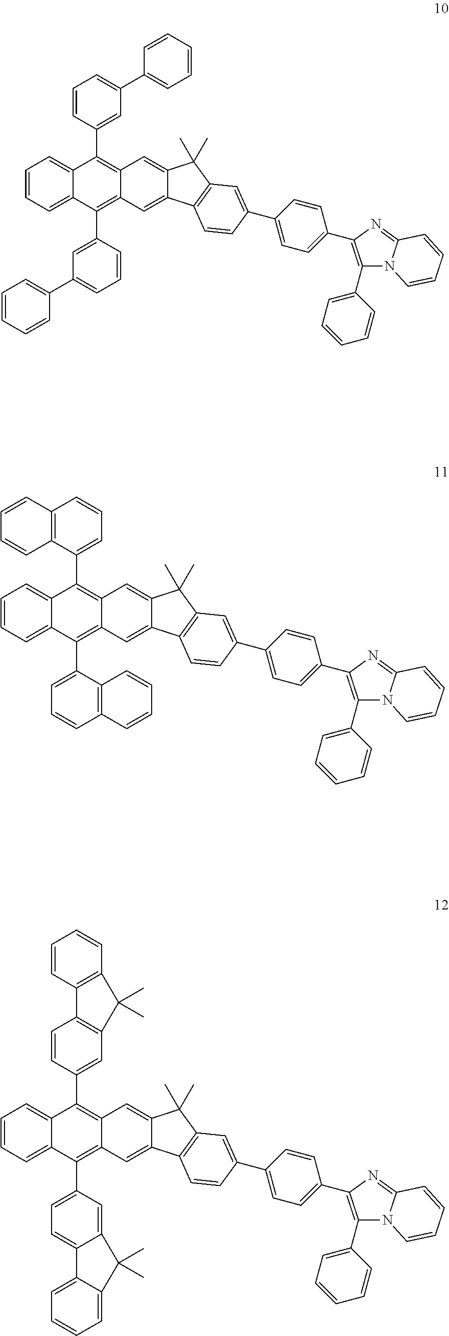 [SMILES: CC1(C)c2cc(-c3ccc(-c4nc5ccccn5c4-c4ccccc4)cc3)ccc2-c2cc3c(-c4cccc(-c5ccccc5)c4)c4ccccc4c(-c4cccc(-c5ccccc5)c4)c3cc21 ; CC1(C)c2cc(-c3ccc(-c4nc5ccccn5c4-c4ccccc4)cc3)ccc2-c2cc3c(-c4cccc5ccccc45)c4ccccc4c(-c4cccc5ccccc45)c3cc21 ; CC1(C)c2ccccc2-c2ccc(-c3c4ccccc4c(-c4ccc5c(c4)C(C)(C)c4ccccc4-5)c4cc5c(cc34)-c3ccc(-c4ccc(-c6nc7ccccn7c6-c6ccccc6)cc4)cc3C5(C)C)cc21]

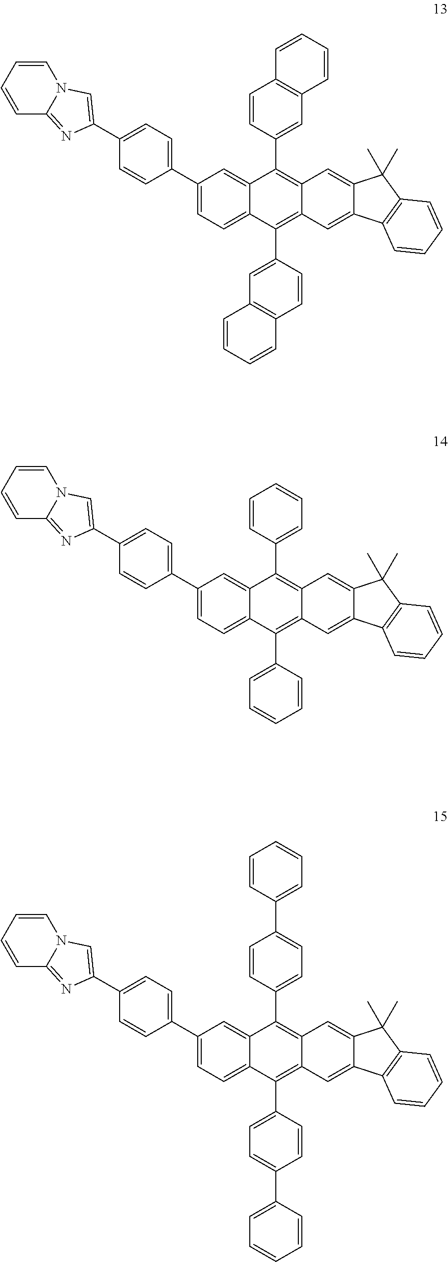 [SMILES: CC1(C)c2ccccc2-c2cc3c(-c4ccc5ccccc5c4)c4ccc(-c5ccc(-c6cn7ccccc7n6)cc5)cc4c(-c4ccc5ccccc5c4)c3cc21 ; CC1(C)c2ccccc2-c2cc3c(-c4ccccc4)c4ccc(-c5ccc(-c6cn7ccccc7n6)cc5)cc4c(-c4ccccc4)c3cc21 ; CC1(C)c2ccccc2-c2cc3c(-c4ccc(-c5ccccc5)cc4)c4ccc(-c5ccc(-c6cn7ccccc7n6)cc5)cc4c(-c4ccc(-c5ccccc5)cc4)c3cc21]

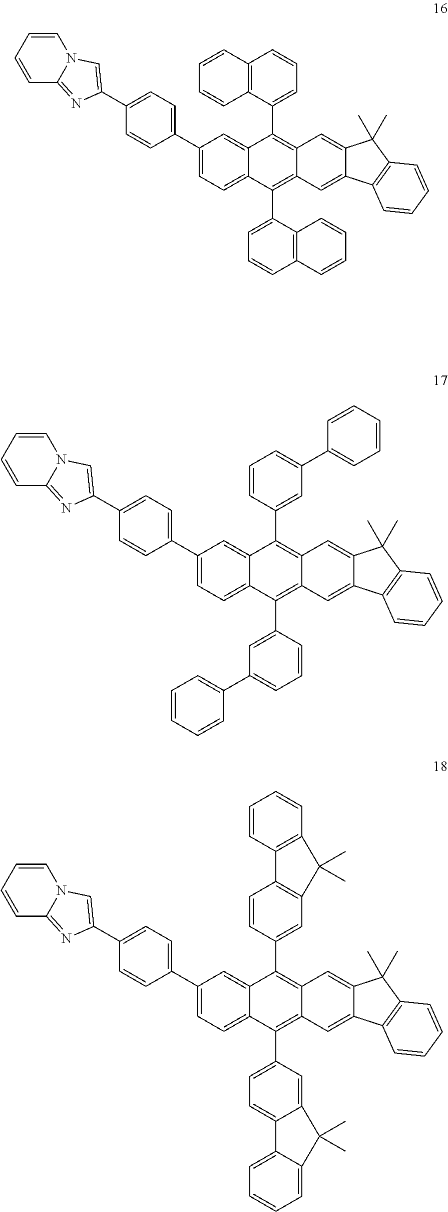 [SMILES: CC1(C)c2ccccc2-c2cc3c(-c4cccc5ccccc45)c4ccc(-c5ccc(-c6cn7ccccc7n6)cc5)cc4c(-c4cccc5ccccc45)c3cc21 ; CC1(C)c2ccccc2-c2cc3c(-c4cccc(-c5ccccc5)c4)c4ccc(-c5ccc(-c6cn7ccccc7n6)cc5)cc4c(-c4cccc(-c5ccccc5)c4)c3cc21 ; CC1(C)c2ccccc2-c2ccc(-c3c4ccc(-c5ccc(-c6cn7ccccc7n6)cc5)cc4c(-c4ccc5c(c4)C(C)(C)c4ccccc4-5)c4cc5c(cc34)-c3ccccc3C5(C)C)cc21]

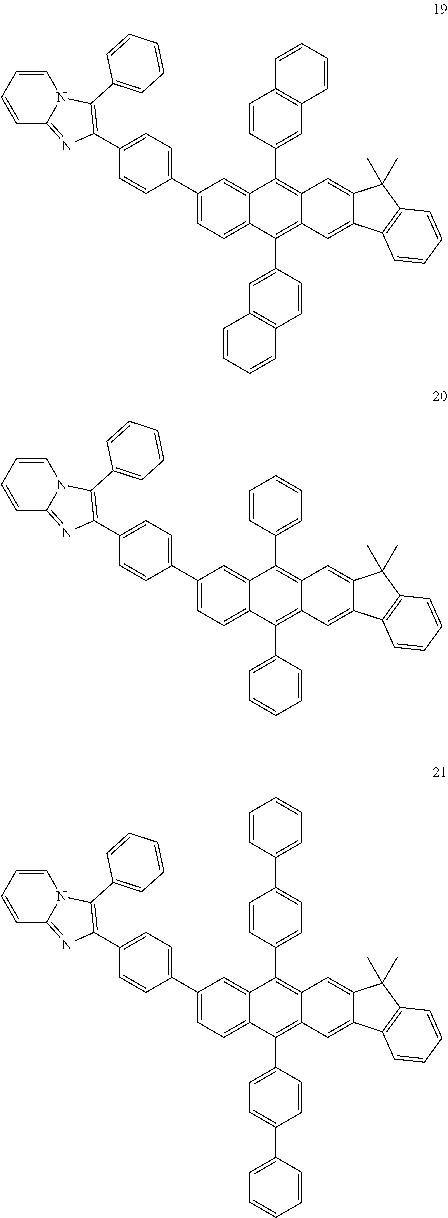 [SMILES: CC1(C)c2ccccc2-c2cc3c(-c4ccc5ccccc5c4)c4ccc(-c5ccc(-c6nc7ccccn7c6-c6ccccc6)cc5)cc4c(-c4ccc5ccccc5c4)c3cc21 ; CC1(C)c2ccccc2-c2cc3c(-c4ccccc4)c4ccc(-c5ccc(-c6nc7ccccn7c6-c6ccccc6)cc5)cc4c(-c4ccccc4)c3cc21 ; CC1(C)c2ccccc2-c2cc3c(-c4ccc(-c5ccccc5)cc4)c4ccc(-c5ccc(-c6nc7ccccn7c6-c6ccccc6)cc5)cc4c(-c4ccc(-c5ccccc5)cc4)c3cc21]

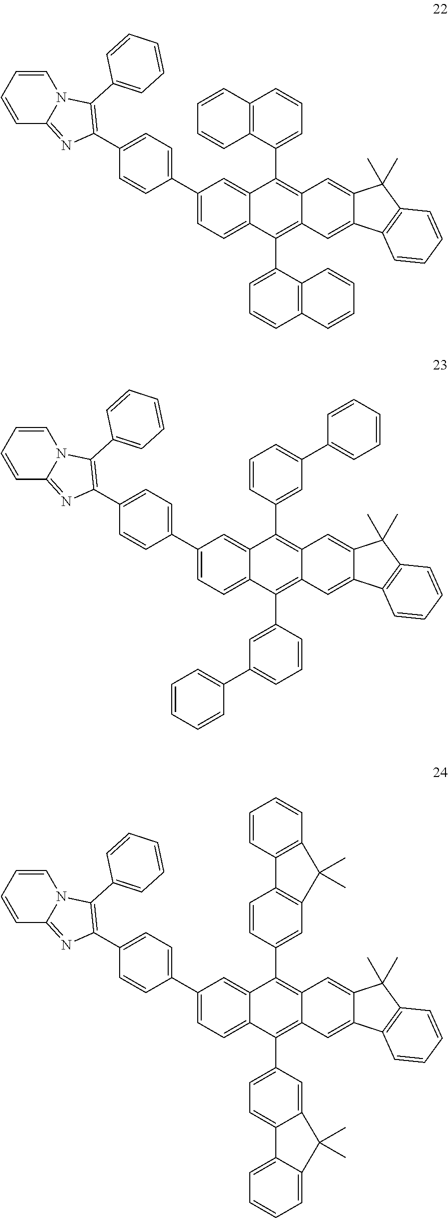 [SMILES: CC1(C)c2ccccc2-c2cc3c(-c4cccc5ccccc45)c4ccc(-c5ccc(-c6nc7ccccn7c6-c6ccccc6)cc5)cc4c(-c4cccc5ccccc45)c3cc21 ; CC1(C)c2ccccc2-c2cc3c(-c4cccc(-c5ccccc5)c4)c4ccc(-c5ccc(-c6nc7ccccn7c6-c6ccccc6)cc5)cc4c(-c4cccc(-c5ccccc5)c4)c3cc21 ; CC1(C)c2ccccc2-c2ccc(-c3c4ccc(-c5ccc(-c6nc7ccccn7c6-c6ccccc6)cc5)cc4c(-c4ccc5c(c4)C(C)(C)c4ccccc4-5)c4cc5c(cc34)-c3ccccc3C5(C)C)cc21]

At least one substituent of the substituted C₃-C₁₀ cycloalkylene group, the substituted C₂-C₁₀ heterocycloalkylene group, the substituted C₃-C₁₀ cycloalkenylene group, the substituted C₂-C₁₀ heterocycloalkenylene group, the substituted C₆-C₆₀ arylene group, the substituted C₂-C₆₀ heteroarylene group, the substituted C₃-C₁₀ cycloalkyl group, the substituted C₂-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₂-C₆₀ heteroaryl group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₆-C₆₀ aryloxy group, and the substituted C₆-C₂₀ arylthio group may be selected from:

a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, and a C₂-C₆₀ heteroaryl group;

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, and a C₂-C₆₀ heteroaryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₅₀ alkynyl group a C₁-C₆₀ alkoxy group, a phenyl group, a naphthyl group, an anthryl group, a fluorenyl group, a dimethyl fluorenyl group, a diphenyl fluorenyl group, a carbazolyl group, a phenyl carbazolyl group, a pyridinyl group, a pyrimidinyl group, a pyrazinyl group, a pyridazinyl group, a triazinyl group, a quinolinyl group, and an isoquinolinyl group; and —N(Q₁₁)(Q₁₂), and —Si(Q₁₃)(Q₁₄)(Q₁₅) (wherein, Q₁₁ to Q₁₅ are, each independently, a C₁-C₆₀ alkyl group, a C₁-C₆₀ alkoxy group, a C₆-C₆₀ aryl group, or a C₂-C₆₀ heteroaryl group); but is not limited thereto.

In one embodiment, an anthracene-based compound represented by Formula 1 above includes an indenoanthracene core and a group represented by Formula 2, and accordingly, this compound has excellent electron transport capabilities.

In one embodiment, an organic light emitting diode including the anthracene-based compound represented by Formula 1 above has low driving voltage, high efficiency, high brightness and a long lifespan.

The anthracene-based compound of Formula 1 may be synthesized by using a suitable organic synthesis method. A method of synthesizing the anthracene-based compound may be inferred by a person in the art based on the Examples below.

The anthracene-based compound of Formula 1 above may be used between a pair of electrodes of the organic light emitting diode. For example, the anthracene-based compound is used in the emission layer and/or in an electron transport region (for example, a hole blocking layer, an electron injection layer, and an electron transport layer) between the emission layer and a cathode. According to an embodiment of the present disclosure, the anthracene-based compound is included in the electron transport region (for example, the electron transport layer). According to another embodiment of the present disclosure, the anthracene-based compound is included in the emission layer.

Accordingly, there is provided an organic light emitting diode including a first electrode; a second electrode disposed opposite to the first electrode, and an organic layer disposed between the first electrode and the second electrode, wherein the organic layer includes at least one of the anthracene-based compounds represented by Formula 1 above. Here, the organic layer includes the hole transport region between the first electrode and the emission layer, and the electron transport region between the emission layer and the second electrode. The anthracene-based compound may exist in the electron transport region.

The expression “organic layer includes at least one anthracene-based compound” as used herein may be construed as “organic layer includes one anthracene-based compound included in Formula 1 or two or more of different anthracene-based compounds included in Formula 1.”

For example, the organic layer only includes Compound 1 above as the anthracene-based compound. Here, Compound 1 may exist in the electron transport layer of the organic light emitting diode. In other embodiments, the organic layer includes Compound 1 and Compound 2 as the anthracene-based compounds. Here, Compound 1 and Compound 2 may exist in the same layer (for example, Compound 1 and Compound 2 may all exist in the electron transport layer, or in different layers (for example, Compound 1 may exist in the electron transport layer and Compound 2 may exist in the emission layer).

The hole transport region of the organic layer may include at least one of a hole injection layer, a hole transport layer, a functional layer having both hole injection and hole transport capabilities (hereinafter, “H-functional layer”), a buffer layer, and an electron blocking layer, and the electron transport region may include at least one of the hole blocking layer, the electron transport layer, and the electron injection layer.

The term “organic layer” as used herein refers to a single layer and/or a plurality of layers disposed between the first and second electrodes of the organic light-emitting diode.

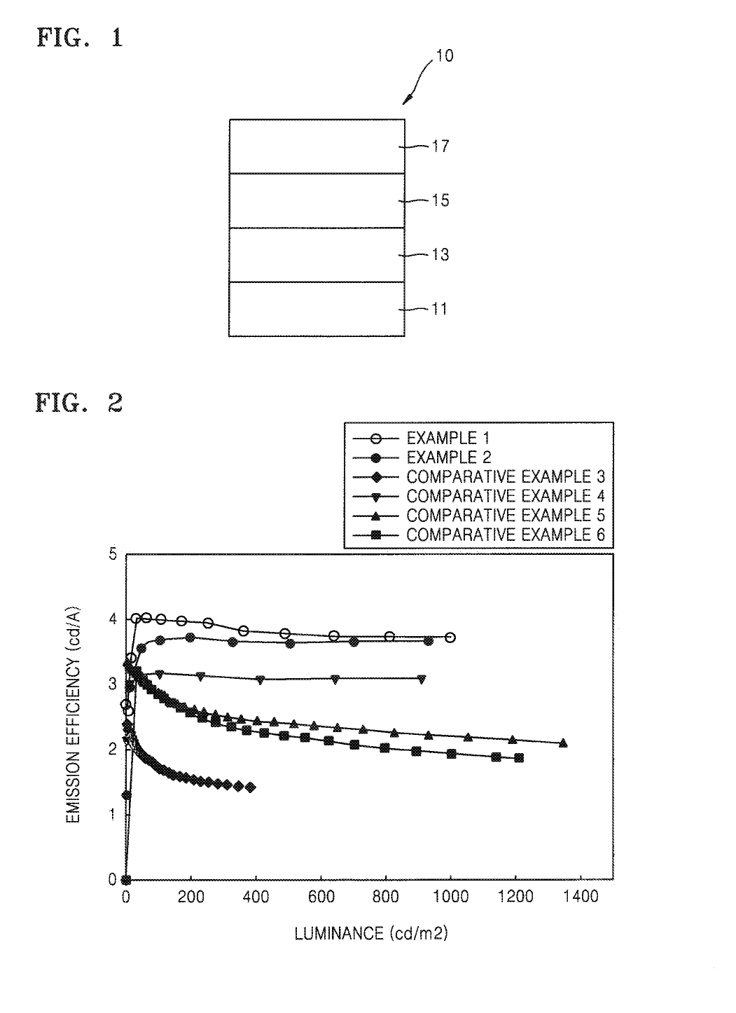

FIG. 1 schematically illustrates a cross section view of an organic light emitting diode 10 according to an embodiment of the present disclosure. Hereinafter, a structure and a method of manufacturing the organic light emitting diode according to an embodiment of the present disclosure will be described with reference to FIG. 1 as follows.

The substrate 11 may be any substrate that is used in existing organic light-emitting diodes. In some embodiments, the substrate 11 is a glass substrate or a transparent plastic substrate with strong mechanical strength, thermal stability, transparency, surface smoothness, ease of handling, and water resistance.

The first electrode 13 may be formed by depositing or sputtering a first electrode forming material onto a surface of the substrate 11. When the first electrode 13 is an anode, a material having a high work function may be used as the first electrode-forming material to facilitate hole injection. The first electrode 13 may be a reflective electrode or a transmission electrode. Transparent and conductive materials such as indium tin oxide (ITO), indium zinc oxide (IZO), tin oxide (SnO₂), and zinc oxide (ZnO) may be used to form the first electrode 13. The first electrode 13 may be formed as a reflective electrode using magnesium (Mg), aluminum (Al), aluminum-lithium (Al—Li), calcium (Ca), magnesium-indium (Mg—In), magnesium-silver (Mg—Ag), or the like.

The first electrode 13 may have a single-layer structure or a multi-layer structure including at least two layers. For example, the first electrode 13 has a three-layered structure of ITO/Ag/ITO, but is not limited thereto.

The organic layer 15 may be disposed on the first electrode 13.

The organic layer 15 may include the hole transport region including a hole injection layer (HIL) and a hole transport layer (HTL), sequentially; an emission layer; and the electron transport region including an electron transport layer (ETL) and an electron injection layer (EIL), sequentially.

The HIL may be formed on the first electrode 13 by vacuum deposition, spin coating, casting, LB deposition, or the like.

When the HIL is formed using vacuum deposition, vacuum deposition conditions may vary according to the compound that is used to form the HIL, and the desired structure and thermal properties of the HIL to be formed. For example, vacuum deposition may be performed at a temperature of about 100° C. to about 500° C., a pressure of about 10⁻⁸ tom to about 10⁻³ torr, and a deposition rate of about 0.01 Å/sec to about 100 Å/sec. However, the deposition conditions are not limited thereto.

When the HIL is formed using spin coating, the coating conditions may vary according to the compound that is used to form the HIL, and the desired structure and thermal properties of the HIL to be formed. For example, the coating rate is in the range of about 2000 rpm to about 5000 rpm, and a temperature at which heat treatment is performed to remove a solvent after coating is in the range of about 80° C. to about 200° C. However, the coating conditions are not limited thereto.

The HIL may be formed of any material described in Formula 1 above. In other embodiments, a suitable HIL material, for example, N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris(3-methylphenylphenylamino)triphenylamine (m-MTDATA), N,N′-di(1-naphthyl group-N,N′-diphenylbenzidine (NPB), TDATA, 2T-NATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), and polyaniline)/poly(4-styrenesulfonate (PANI/PSS), may be used, but is not limited thereto:

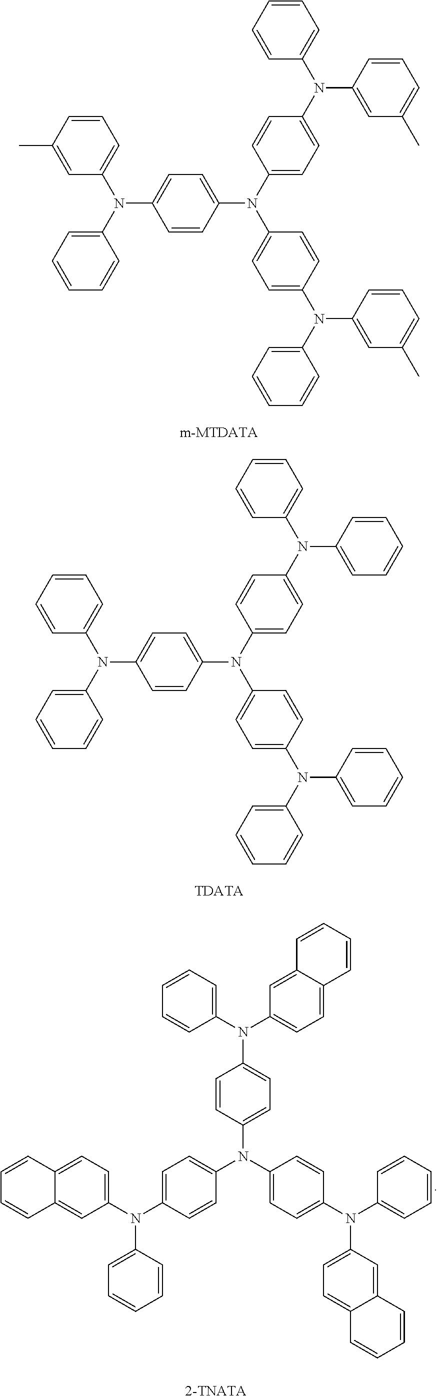

The thickness of the HIL may be about 100 Å to about 10000 Å, and in some embodiments, is from about 100 Å to about 1000 Å. In one embodiment, when the thickness of the HIL is within these ranges, the HIL has good hole injecting ability without a substantial increase in the driving voltage.

Then, a HTL may be formed on the HIL by using vacuum deposition, spin coating, casting, LB deposition, or the like. When the HTL is formed using vacuum deposition or spin coating, the conditions for deposition and coating may be similar to those for the formation of the HIL, though the conditions for the deposition and coating may vary according to the material that is used to form the HTL.

In some embodiments, a suitable hole transport layer material such as carbazole derivatives, such as N-phenylcarbazole or polyvinylcarbazole, N,N′-bis(3-methylphenyl)-N,N′-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine) (NPB) may be used, but is not limited thereto.

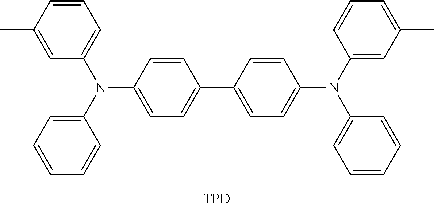

The thickness of the HTL may be from about 50 Å to about 2000 Å, and in some embodiments, is from about 100 Å to about 1500 Å. In one embodiment, when the thickness of the HTL is within these ranges, the HTL has good hole transporting ability without a substantial increase in the driving voltage.

On the other hand, the organic light emitting diode 10 may include an H-functional layer (having both hole injection and hole transport capabilities) instead of the HIL and the HTL. The H-functional layer may contain at least one material from each group of the hole injection layer materials and hole transport layer materials. The thickness of the H-functional layer may be from about 100 Å to about 10,000 Å, and in some embodiments, is from about 100 Å to about 1,000 Å. In one embodiment, when the thickness of the H-functional layer is within these ranges, the H-functional layer has good hole injection and transport capabilities without a substantial increase in the driving voltage.

In some embodiments, at least one of the HIL, HTL, and H-functional layer includes at least one of a compound of Formula 300 below and a compound of Formula 301 below:

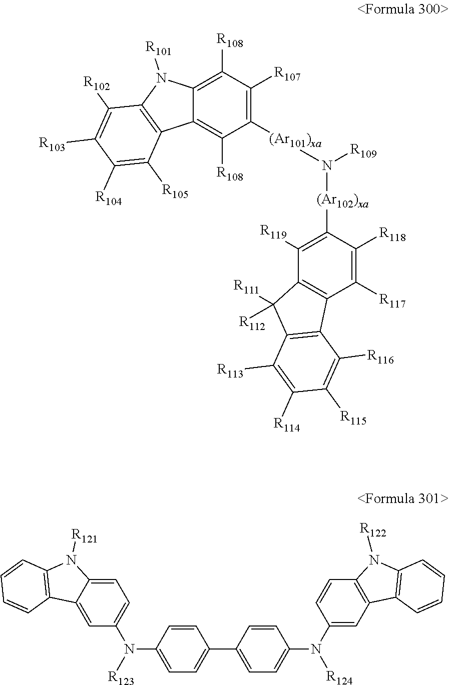

In Formula 300, Ar₁₀₁ and Ar₁₀₂ are, each independently, a substituted or unsubstituted C₆-C₆₀ arylene group.

For example, Ar₁₀₁ and Ar₁₀₂ are, each independently, selected from,

a phenylene group, a pentalenylene group, an indenylene group, a naphthylene group, an azulenylene group, a heptalenylene group, a substituted or unsubstituted an acenaphthylene group, a fluorenylene group, a phenalenylene group, a phenanthrenylene group, an anthrylene group, a fluoranthenylene group, a triphenylenylene group, a pyrenylene group, a chrysenylenylene group, a naphthacenylene group, a picenylene group, a perylenylene group, and a pentacenylene group; and

a phenylene group, a pentalenylene group, an indenylene group, a naphthylene group, an azulenylene group, a heptalenylene group, a substituted or unsubstituted an acenaphthylene group, a fluorenylene group, a phenalenylene group, a phenanthrenylene group, an anthrylene group, a fluoranthenylene group, a triphenylenylene group, a pyrenylene group, a chrysenylenylene group, a naphthacenylene group, a picenylene group, a perylenylene group, and a pentacenylene group, each substituted with a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, C₁-C₆₀ alkyl group, C₂-C₆₀ alkenyl group, C₂-C₆₀ alkynyl group, C₁-C₆₀ alkoxy group, C₃-C₁₀ cycloalkyl group, C₃-C₁₀ cycloalkenyl group, C₃-C₁₀ heterocycloalkyl group, C₃-C₁₀ heterocycloalkenyl group, C₆-C₆₀ aryl group, C₆-C₆₀ aryloxy group, C₆-C₆₀ arylthio group, and C₂-C₅₀ heteroaryl group.

In Formula 300, xa and xb are, each independently, an integer of 0 to 5. For example, 0, 1 or 2. In one embodiment, xa is 1 and xb is 0, but are not limited thereto.

In Formulae 300 and 301, R₁₀₁ to R₁₀₈, R₁₁₁ to R₁₁₉, and R₁₂₁ to R₁₂₄ may be, each independently, a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₆-C₆₀ aryl group, a substituted or unsubstituted C₆-C₆₀ aryloxy group, or a substituted or unsubstituted C₆-C₆₀ arylthio group.

For example, R₁₀₁ to R₁₀₈, R₁₁₁ to R₁₁₉, and R₁₂₁ to R₁₂₄ are, each independently, selected from

a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, and a hexyl group) and C₁-C₁₀ alkoxy group (for example, a methoxy group, an ethoxy group, a propoxy group, a butoxy group, and a pentoxy group);

a C₁-C₁₀ alkyl group and a C₁-C₁₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

a phenyl group, a naphthyl group, an anthryl group, a fluorenyl group, and a pyrenyl group; and

a phenyl group, a naphthyl group, an anthryl group, a fluorenyl group, and a pyrenyl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, C₁-C₁₀ alkyl group, and C₁-C₁₀ alkoxy group, but are not limited thereto.

In Formula 300, R₁₀₉ may be selected from,

a phenyl group, a naphthyl group, an anthryl group, a biphenyl group, and a pyridyl group; and

a phenyl group, a naphthyl group, an anthryl group, a biphenyl group, and a pyridyl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

According to an embodiment of the present disclosure, the compound represented by Formula 300 is represented by Formula 300A, but are not limited thereto:

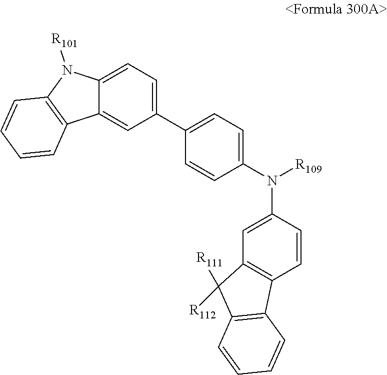

In Formula 300A, R₁₀₁, R₁₁₁, R₁₁₂ and R₁₀₉ are as defined above.

In some non-limiting embodiments, at least one of the HIL, HTL, and H-functional layer includes at least one of the compounds represented by Formulae 301 to 320 below, but are not limited thereto:

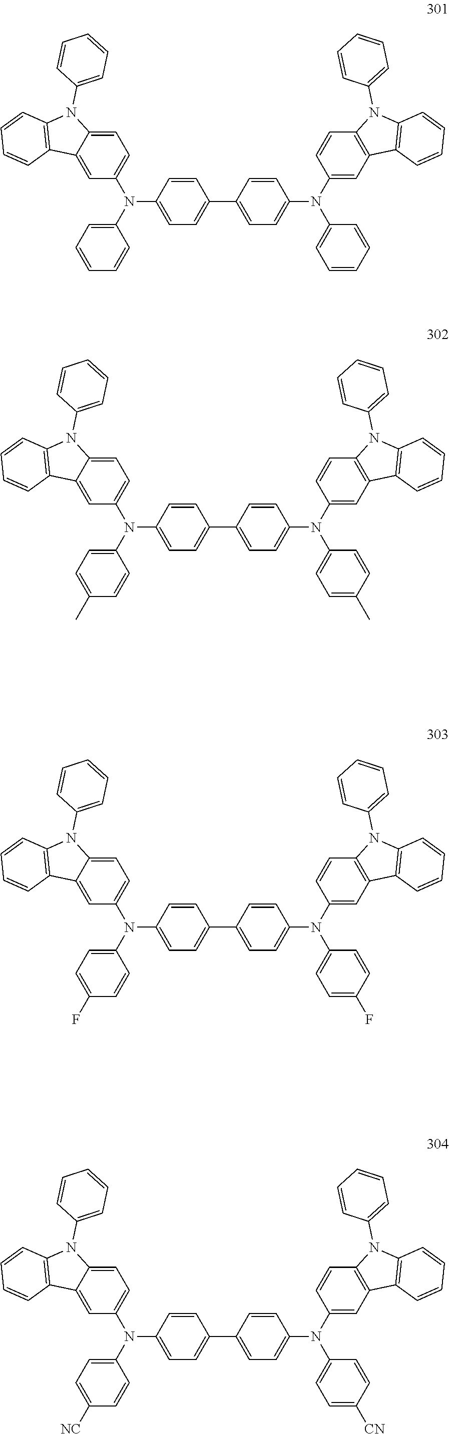 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

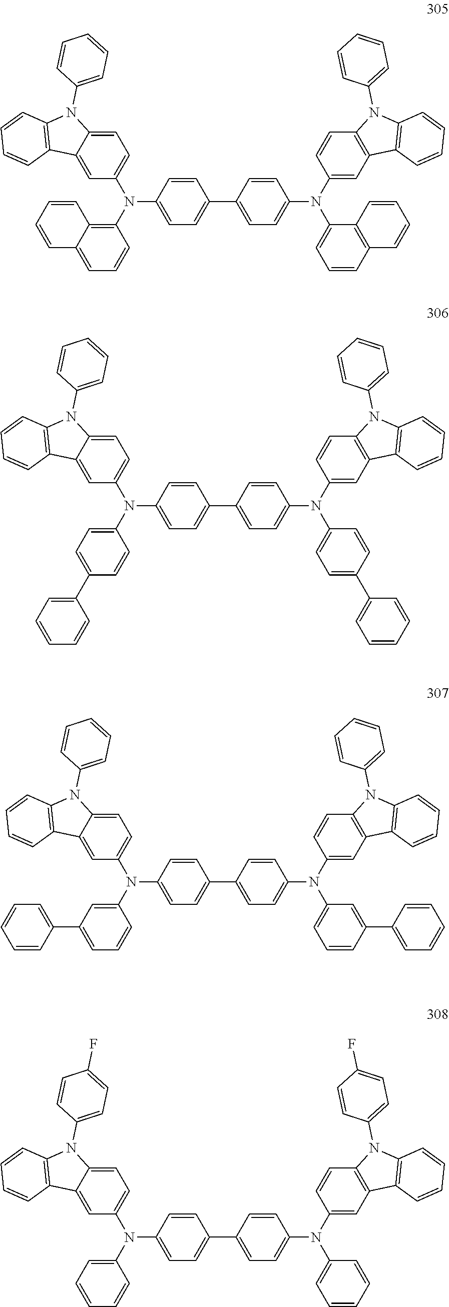 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

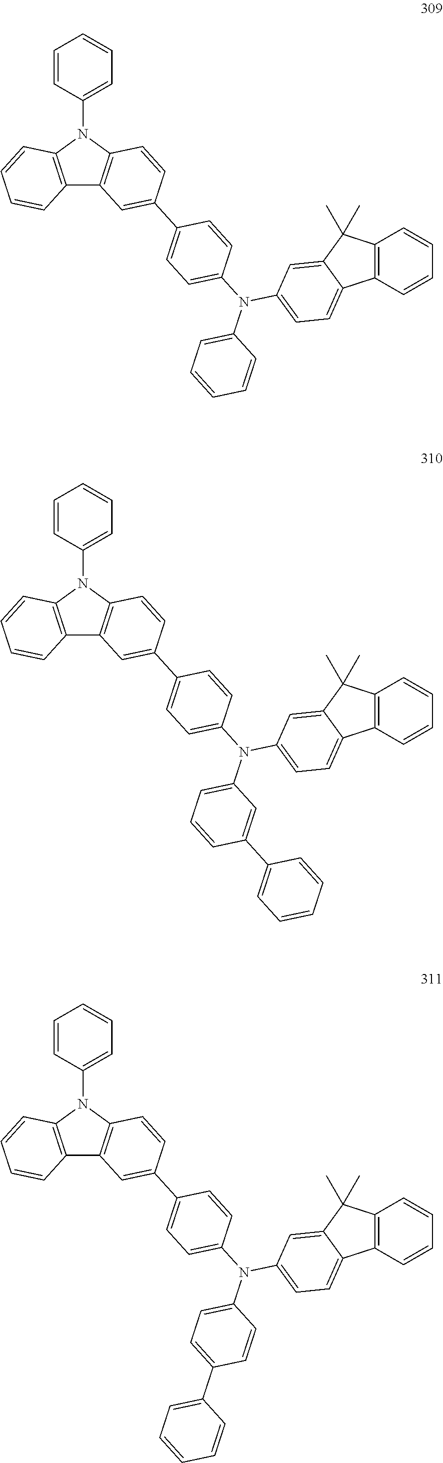 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

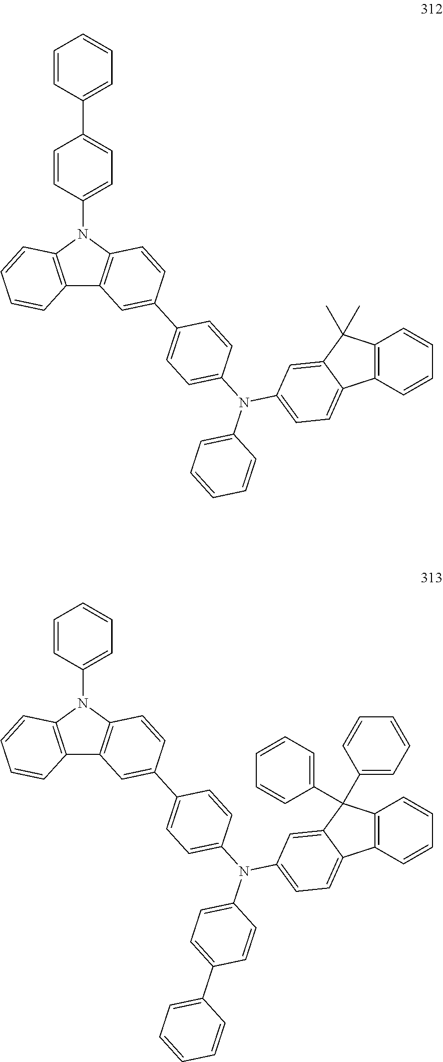 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

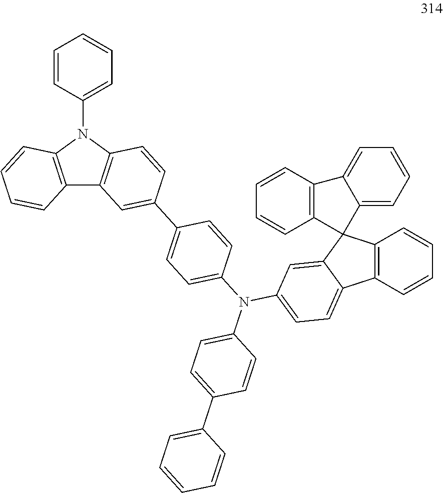 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

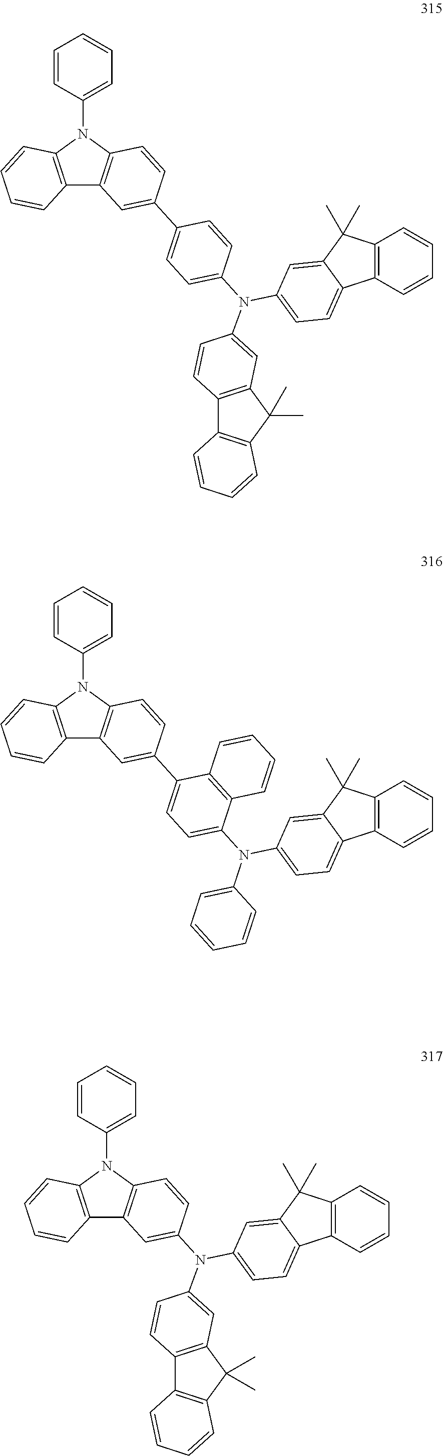 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

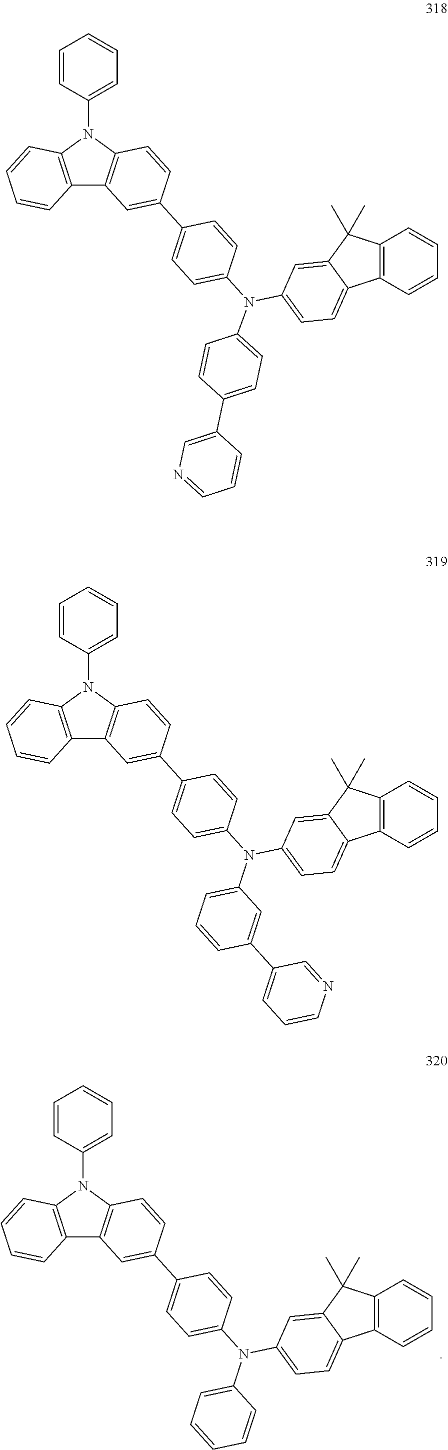 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccccc3)c3ccc(-c4ccc5c(c4)c4ccccc4n5-c4ccccc4)cc3)cc21 ; "."]

The hole transport region may include a charge-generating material for improved layer conductivity, in addition to the HIL described above and/or a suitable hole transport material.

The charge-generating material may be, for example, a p-dopant. The p-dopant may be one of quinone derivatives, metal oxides, and compounds with a cyano group, but are not limited thereto. Non-limiting examples of the p-dopant are quinone derivatives such as tetracyanoquinonedimethane (TCNQ), 2,3,5,6-tetrafluoro-tetracyano-1,4-benzoquinonedimethane (F4-TCNQ), and the like; metal oxides such as tungsten oxide, molybdenum oxide, and the like; and cyano-containing compounds such as Compound 200 below.

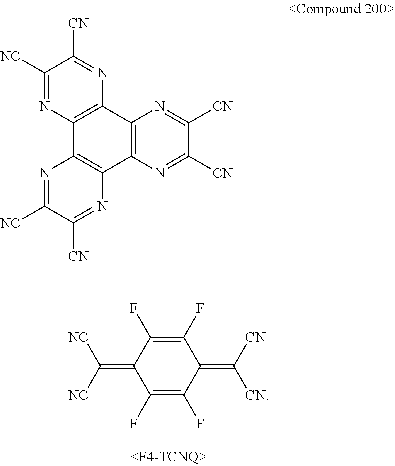 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

When the hole transport region further includes a charge-generating material, the charge generating material may be homogeneously dispersed or inhomogeneously distributed in the layer.

The hole transport region may further include a buffer layer between the HTL and the EML (or between the H-functional layer and the EML).

The buffer layer may compensate for an optical resonance distance of light according to a wavelength of the light emitted from the EML, and thus may increase efficiency. The buffer layer may include any hole injecting material or hole transporting material that are suitable. In some other embodiments, the buffer layer may include the same material as one of the materials included in the HTL (or the H-functional layer) that underlies the buffer layer.

Then, an EML may be formed on the hole transport region by vacuum deposition, spin coating, casting, Langmuir-Blodget (LB) deposition, or the like. When the EML is formed using vacuum deposition or spin coating, the deposition and coating conditions may be similar to those for the formation of the HIL, though the conditions for deposition and coating may vary according to the material that is used to form the EML.

The emission layer may include a host, and a dopant.

As the host, Alq₃, CBP(4,4′-N,N′-dicarbazole-biphenyl), PVK (poly(n-vinylcarbazole)), 9,10-di(naphthalene-2-yl)anthracene (ADN), TCTA, TPBI (1,3,5-tris(N-phenylbenzimidazole-2-yl)benzene(1,3,5-tris(N-phenylbenzimidazole-2-yl)benzene)), TBADN (3-tert-butyl-9,10-di(napth-2-yl)anthracene), E3, DSA (distyrylarylene), dmCBP (referred to in Formula below), Compounds 501 to 509, or the like may be used, but is not limited thereto.

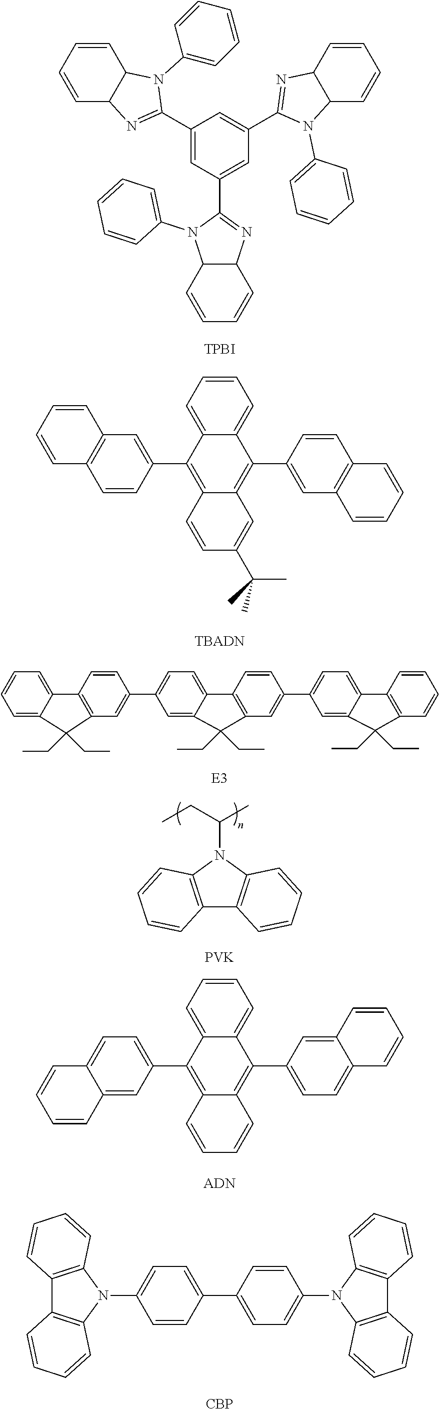

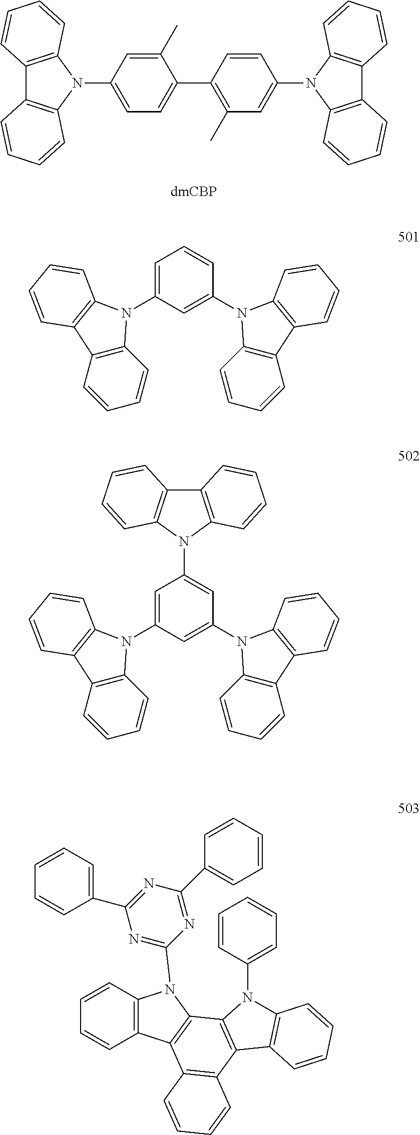 [SMILES: Cc1cc(-n2c3ccccc3c3ccccc32)ccc1-c1ccc(-n2c3ccccc3c3ccccc32)cc1C ; "dmCBP" ; c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1 ; c1ccc(-c2nc(-c3ccccc3)nc(-n3c4ccccc4c4c5ccccc5c5c6ccccc6n(-c6ccccc6)c5c43)n2)cc1]

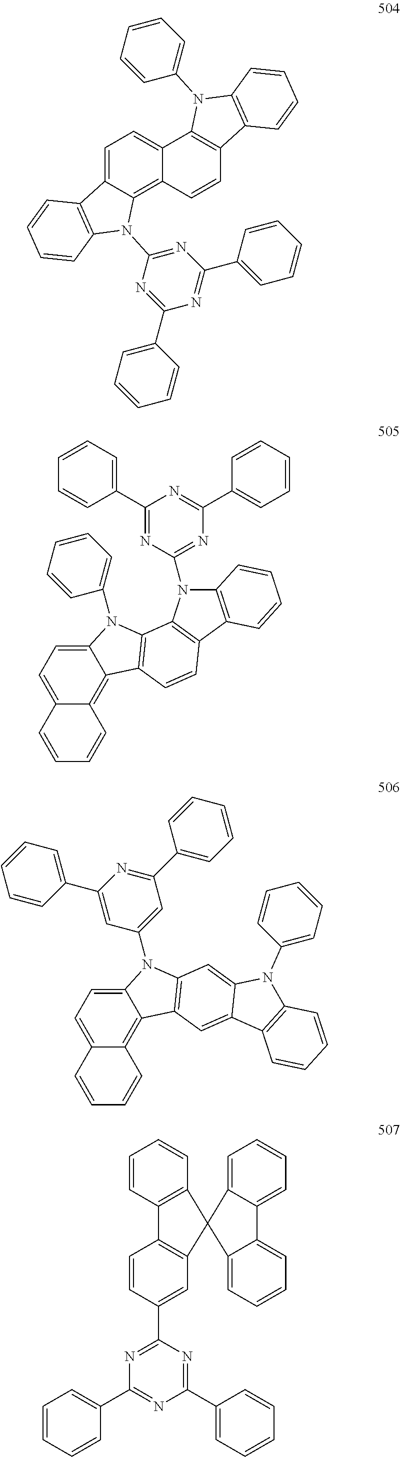 [SMILES: c1ccc(-c2nc(-c3ccccc3)nc(-n3c4ccccc4c4ccc5c(ccc6c7ccccc7n(-c7ccccc7)c65)c43)n2)cc1 ; c1ccc(-c2nc(-c3ccccc3)nc(-n3c4ccccc4c4ccc5c6c7ccccc7ccc6n(-c6ccccc6)c5c43)n2)cc1 ; c1ccc(-c2cc(-n3c4cc5c(cc4c4c6ccccc6ccc43)c3ccccc3n5-c3ccccc3)cc(-c3ccccc3)n2)cc1 ; c1ccc(-c2nc(-c3ccccc3)nc(-c3ccc4c(c3)C3(c5ccccc5-c5ccccc53)c3ccccc3-4)n2)cc1]

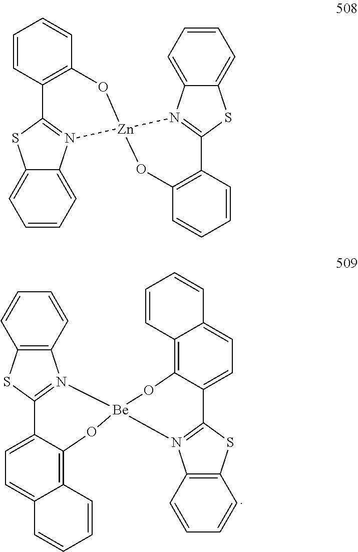

In some embodiments, an anthracene-based compound represented by Formula 400 may be used as the host:

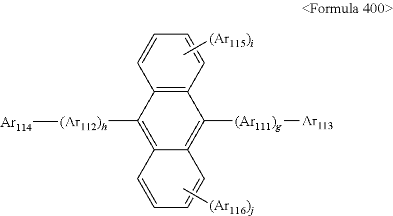

In Formula 400, Ar₁₁₁ and Ar₁₁₂ may be, each independently, a substituted or unsubstituted C₆-C₆₀ arylene group; Ar₁₁₃ to Ar₁₁₆ may be, each independently, a substituted or unsubstituted C₁-C₁₀ alkyl group or a substituted or unsubstituted C₆-C₆₀ aryl group; and g, h, i and j may be, each independently, an integer of 0 to 4.

For example, in Formula 400, Ar₁₁₁ and Ar₁₁₂ are, each independently, selected from a phenylene group, a naphthylene group, a phenanthrenylene group, and a pyrenylene group; and a phenylene group, a naphthylene group, a phenanthrenylene group, a fluorenyl group, and a pyrenylene group, each substituted with at least one of a phenyl group, a naphthyl group, and an anthryl group, but are not limited thereto.

In Formula 400, g, h, i and j may be, each independently, 0, 1 or 2.

In Formula 400, Ar₁₁₃ to Ar₁₁₆ may be, each independently,

a C₁-C₁₀ alkyl group substituted with at least one of a phenyl group, a naphthyl group, and an anthryl group;

a phenyl group, a naphthyl group, an anthryl group, a pyrenyl group, a phenanthrenyl group, and a fluorenyl group;

a phenyl group, a naphthyl group, an anthryl group, a pyrenyl group, a phenanthrenyl group, and a fluorenyl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, C₁-C₆₀ alkyl group, C₂-C₆₀ alkenyl group, C₂-C₆₀ alkynyl group, C₁-C₆₀ alkoxy group, a phenyl group, a naphthyl group, an anthryl group, a pyrenyl group, a phenanthrenyl group, and a fluorenyl group: and

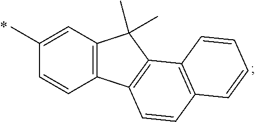 [SMILES: Cc1ccc2c(c1)C(C)(C)c1c-2ccc2ccccc12]

but are not limited thereto,

For example, the anthracene-based compound represented by Formula 400 is one of the compounds below, but is not limited thereto:

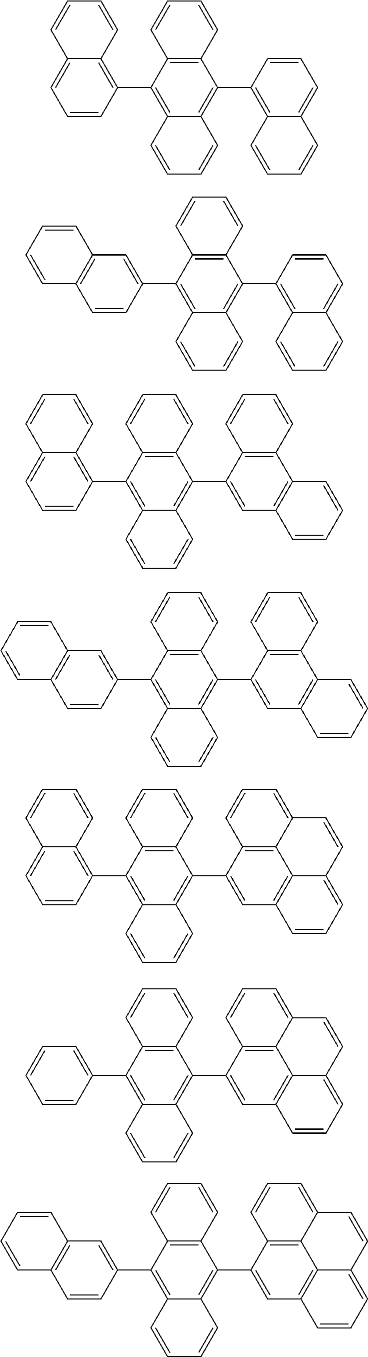

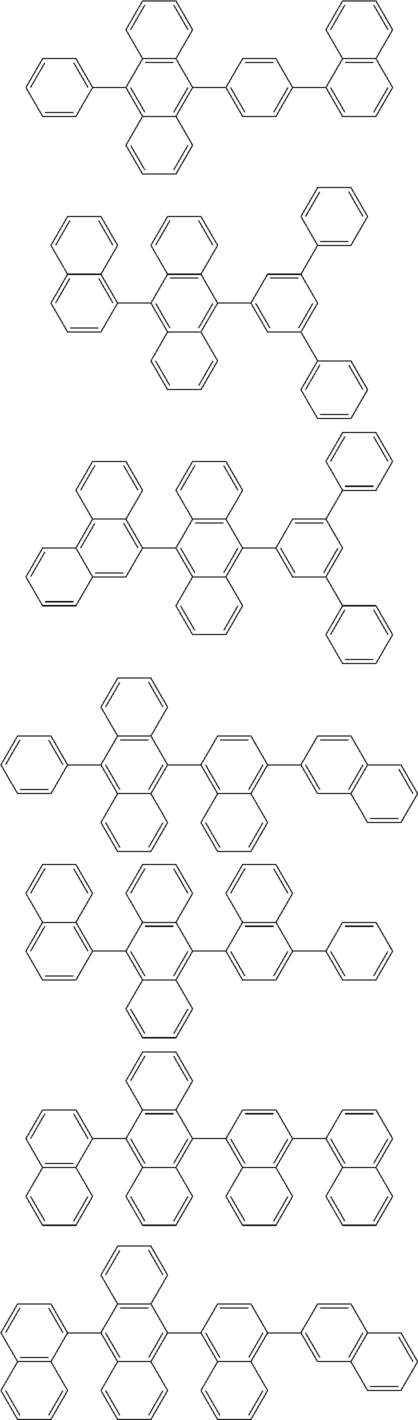

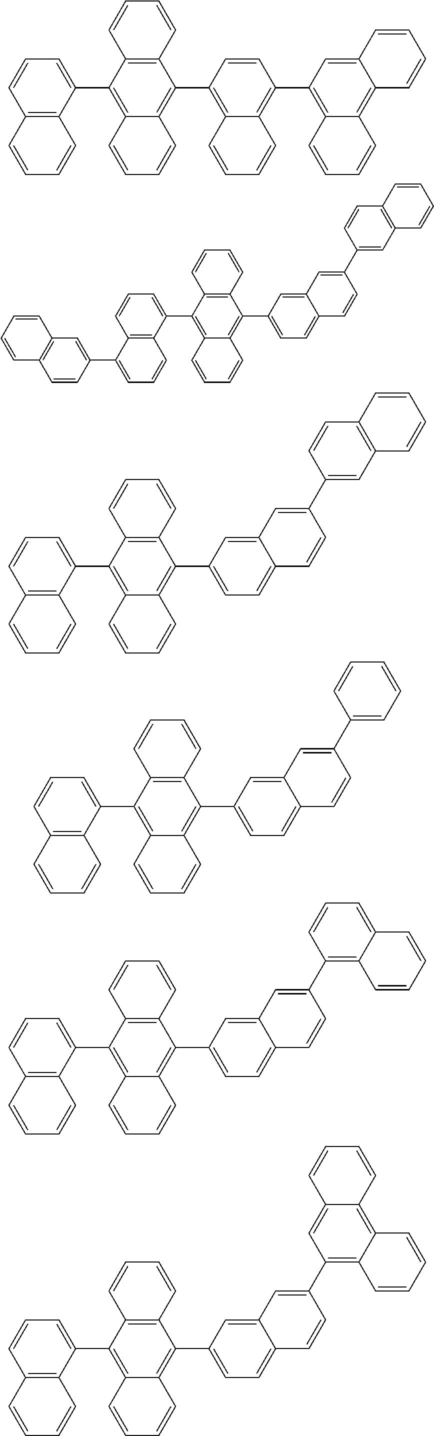

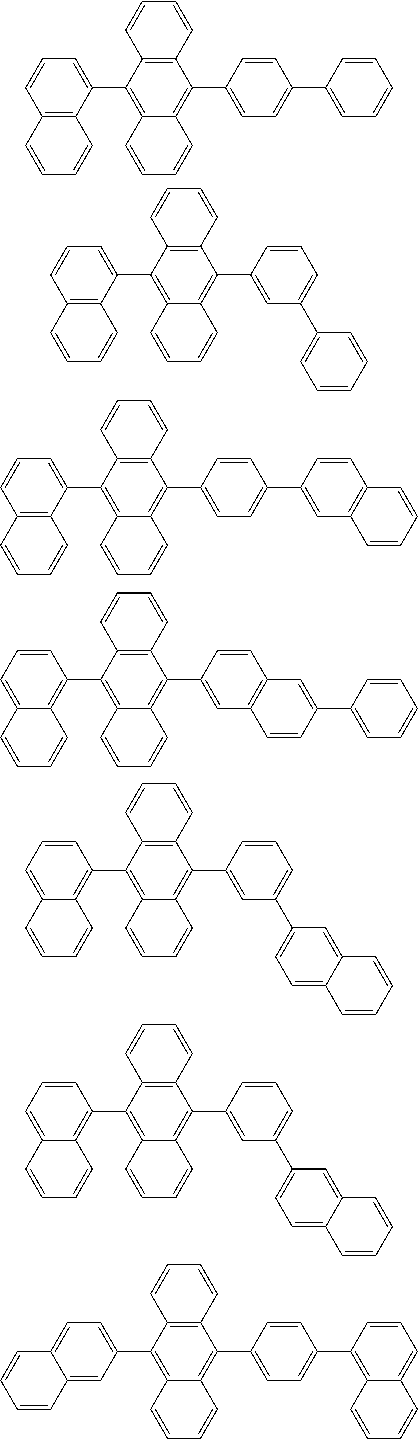

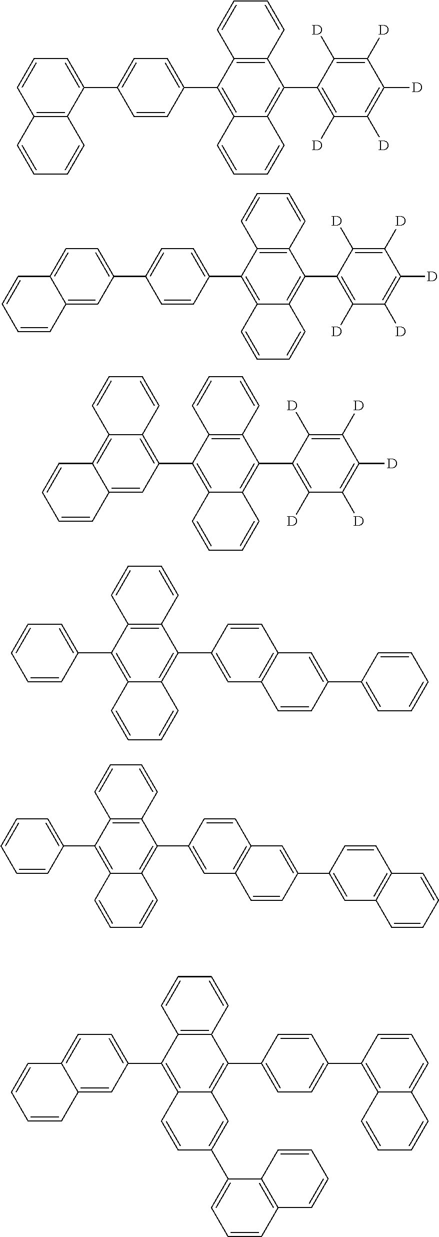

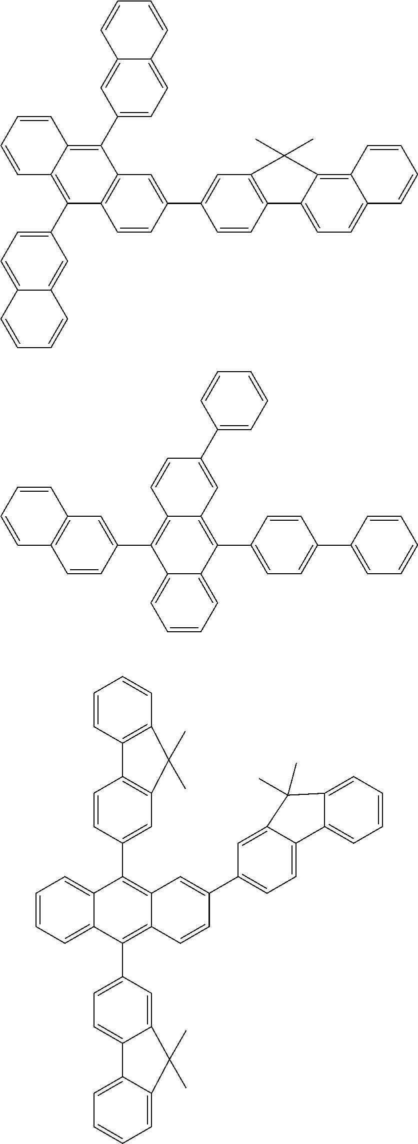

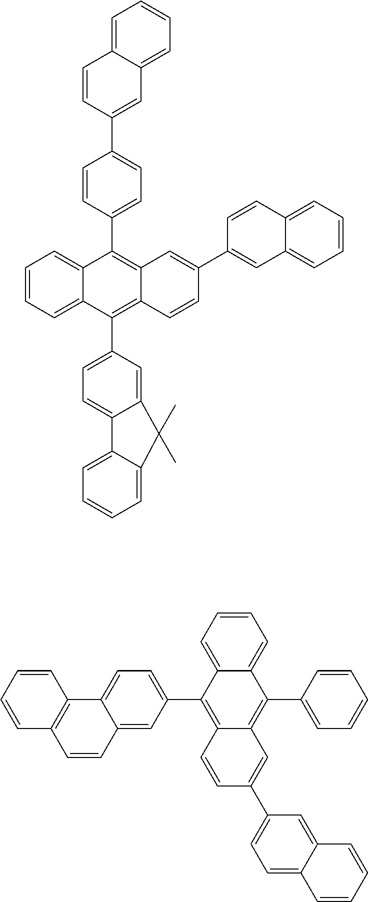

In some embodiments, an anthracene based compound represented by Formula 401 below is used as the host:

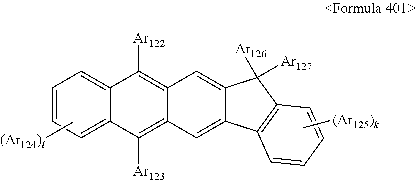

In Formula 401, Ar₁₂₂ to Ar₁₂₅ are defined the same as Ar₁₁₃ in Formula 400 is defined.

In Formula 401, Ar₁₂₆ and Ar₁₂₇ may be, each independently, a C₁-C₁₀ alkyl group (for example, a methyl group, an ethyl group or a propyl group),

In Formula 401, k and l may be, each independently, an integer of 0 to 4. For example, k and l are, each independently, 0, 1 or 2.

For example, the anthracene based compound represented by Formula 401 may be one of the compounds below, but is not limited thereto:

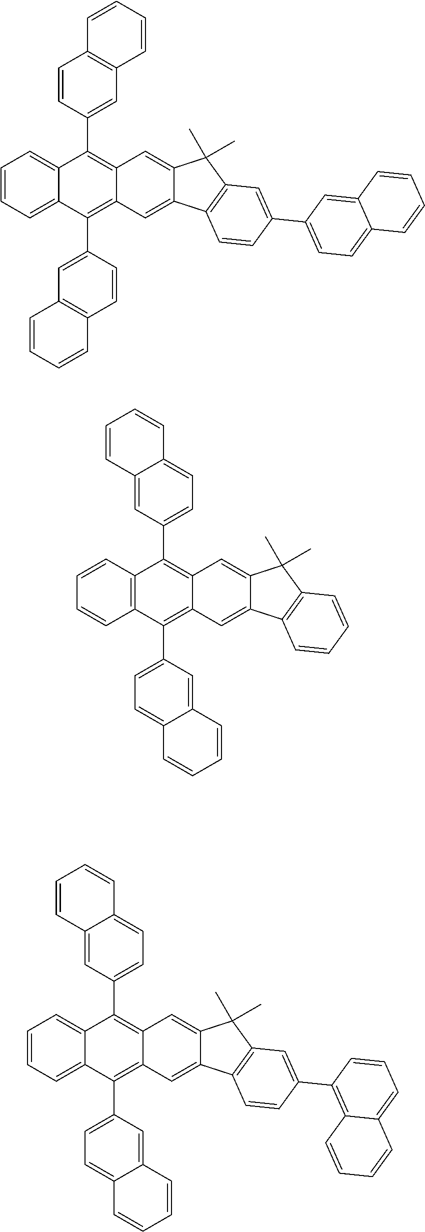

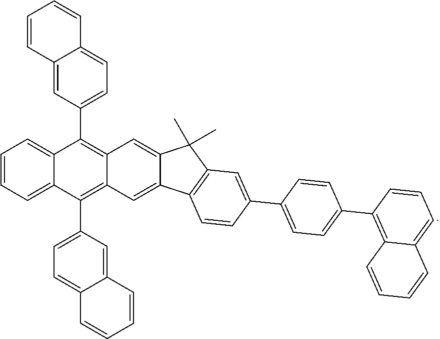 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

When the organic light-emitting diode is a full color organic light-emitting diode, the emission layer may be patterned into a red emission layer, a green emission layer, and/or a blue emission layer. In some embodiments, the emission layer is the red emission layer, the green emission layer, and/or the blue emission layer that are stacked upon one another and emit white light, but is not limited thereto.

The dopant in the emission layer may be at least one selected from suitable dopants.

At least one of the red emission layer, the green emission layer, and the blue emission layer may include a dopant below (ppy=phenylpyridine).

Non-limiting examples of the blue dopant are compounds represented by the following formulae.

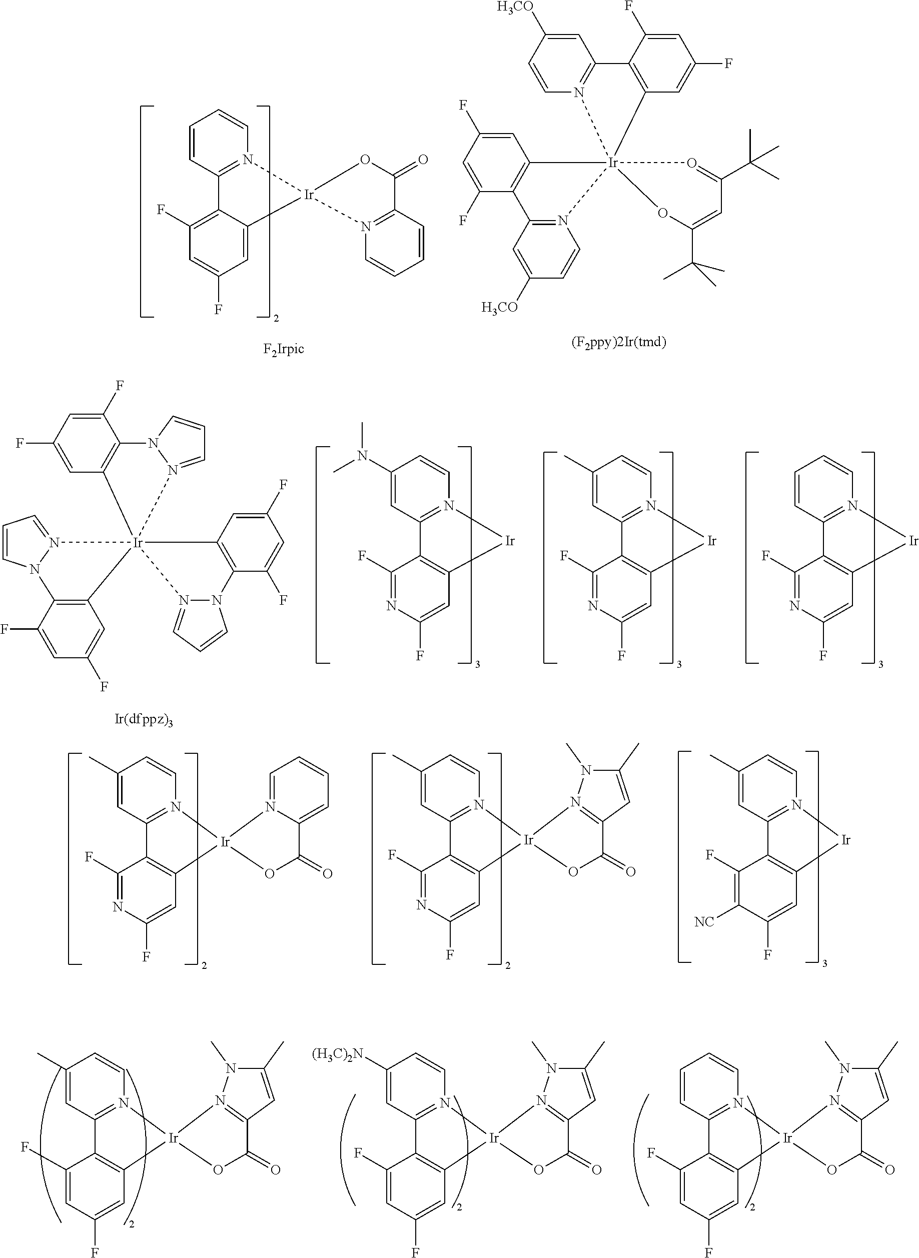

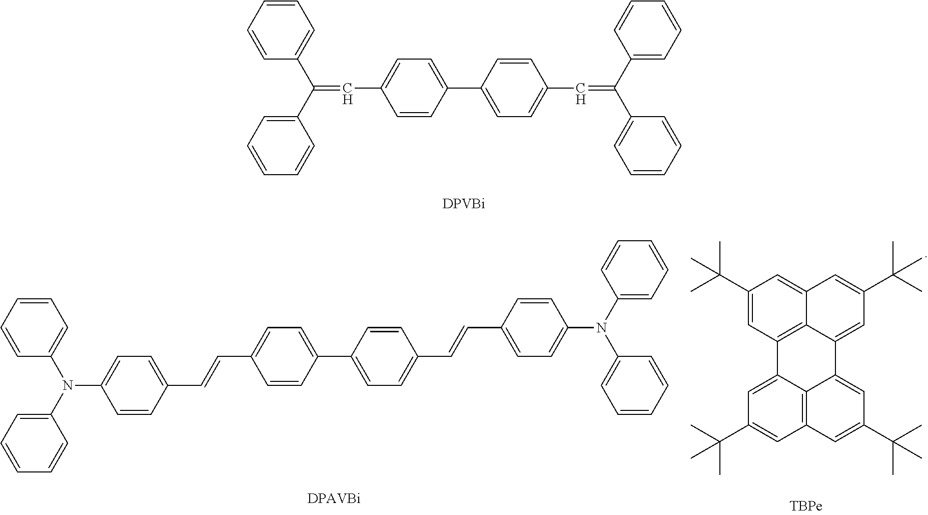

Non-limiting examples of the red dopant are compounds represented by the following formulae. In some embodiments, the red dopant is DCM or DCJTB, which will be described later.

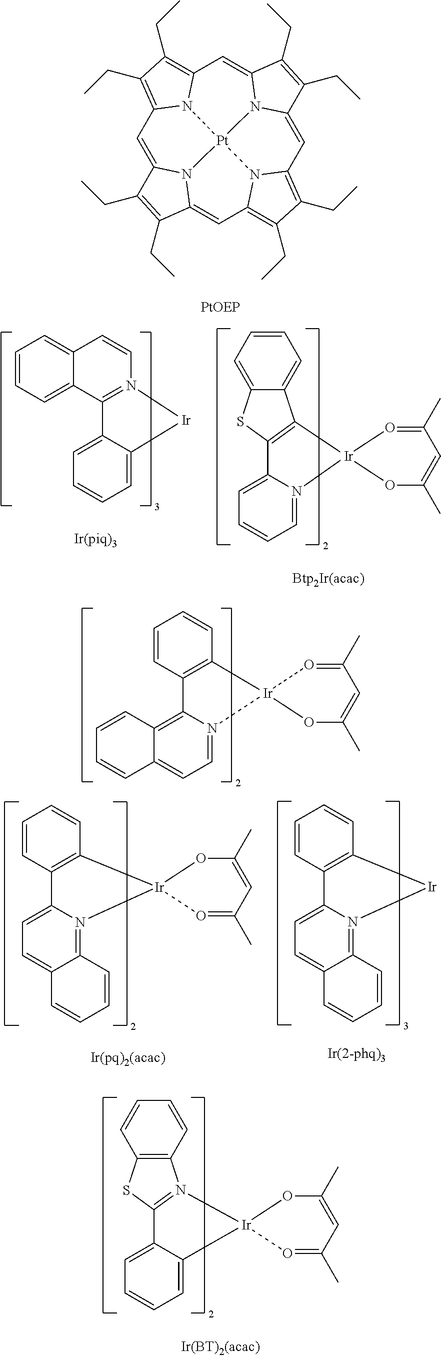

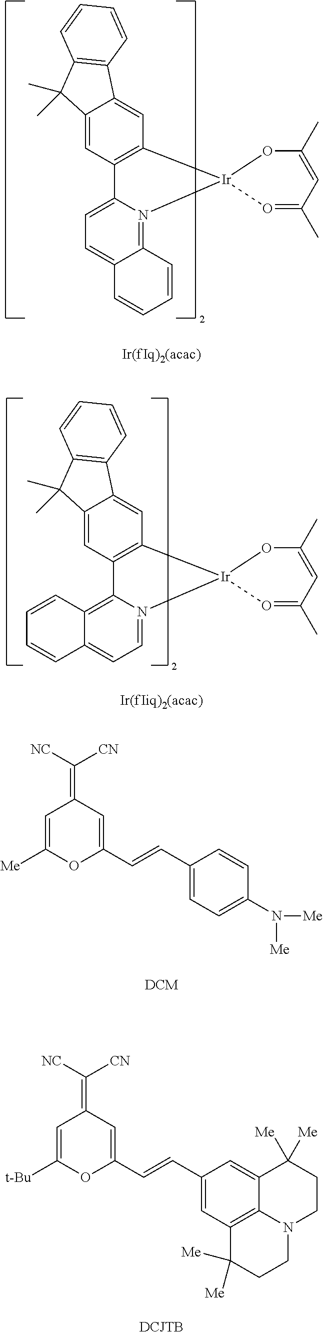

Non-limiting examples of the green dopant are compounds represented by the following formulae. In some embodiments, the green dopant is C545T represented below.

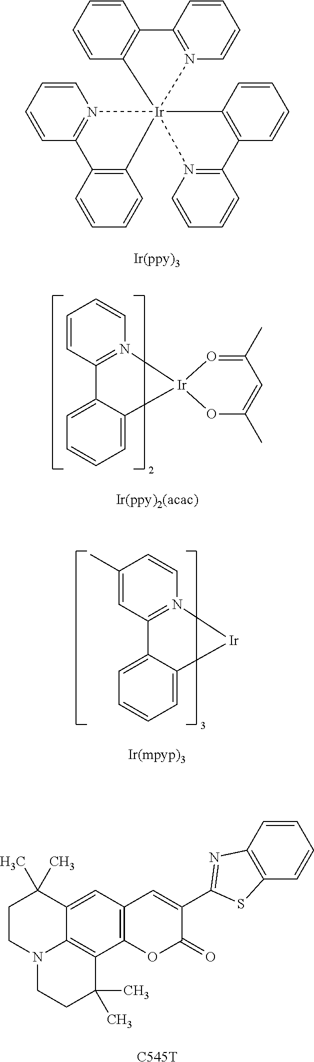

On the other hand, the dopant used in the EML may be a complex described below, but is not limited thereto.

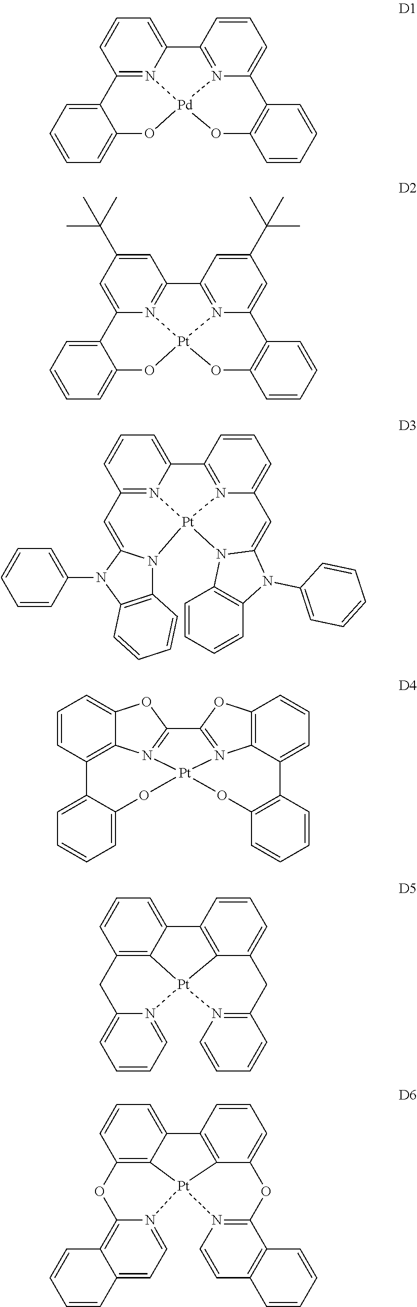

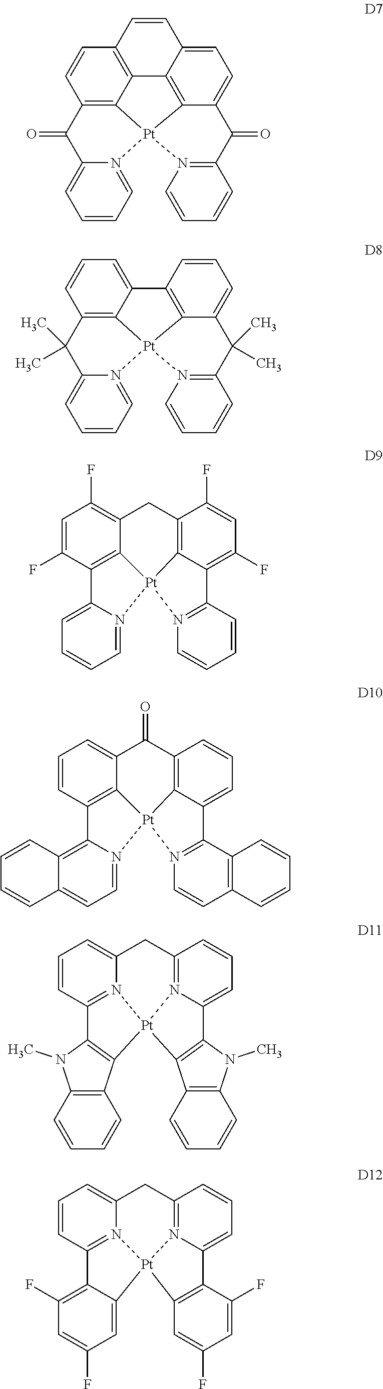

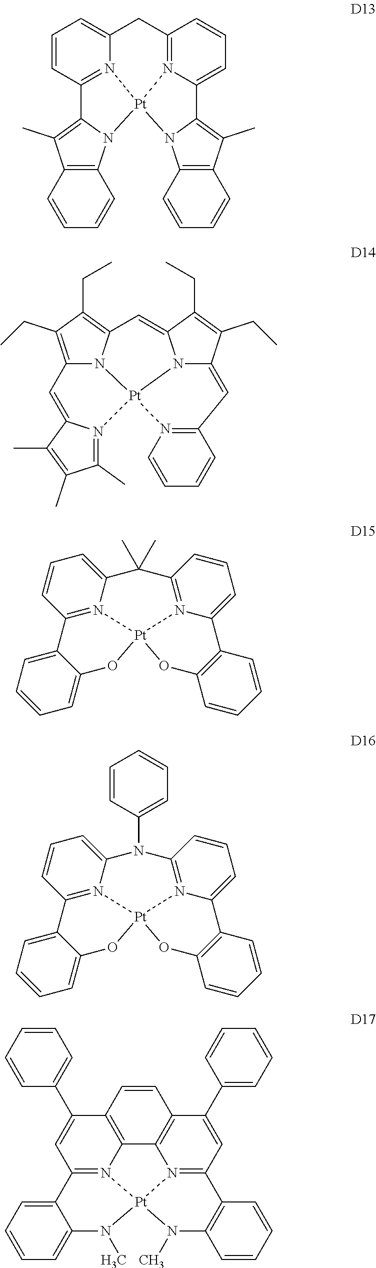

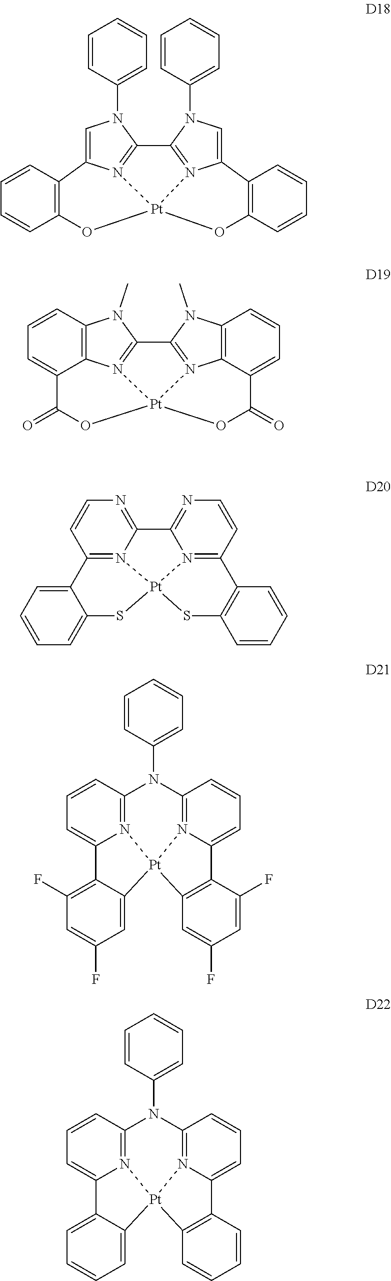

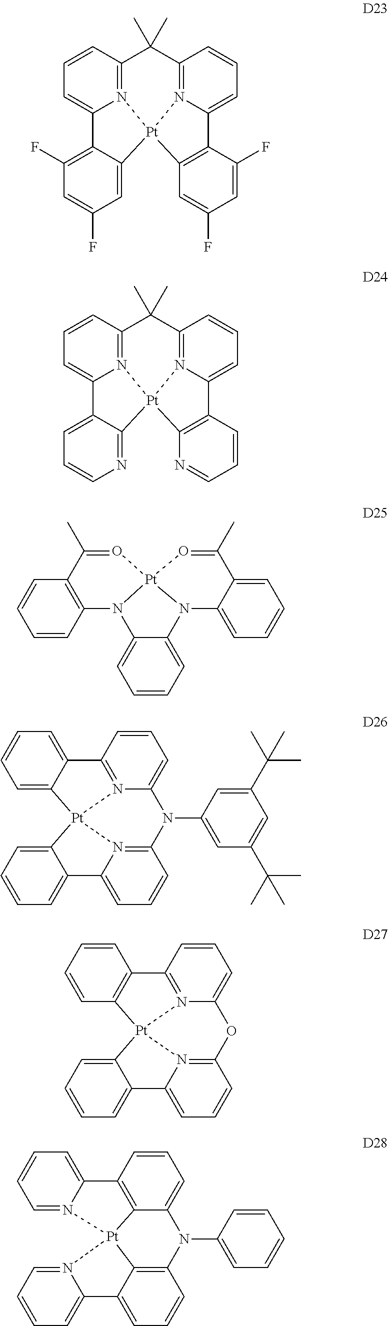

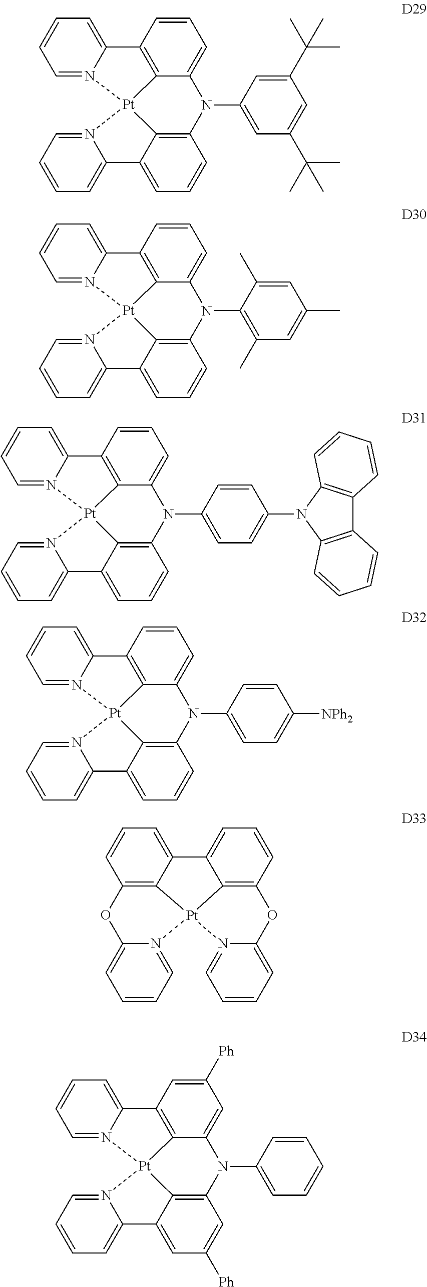

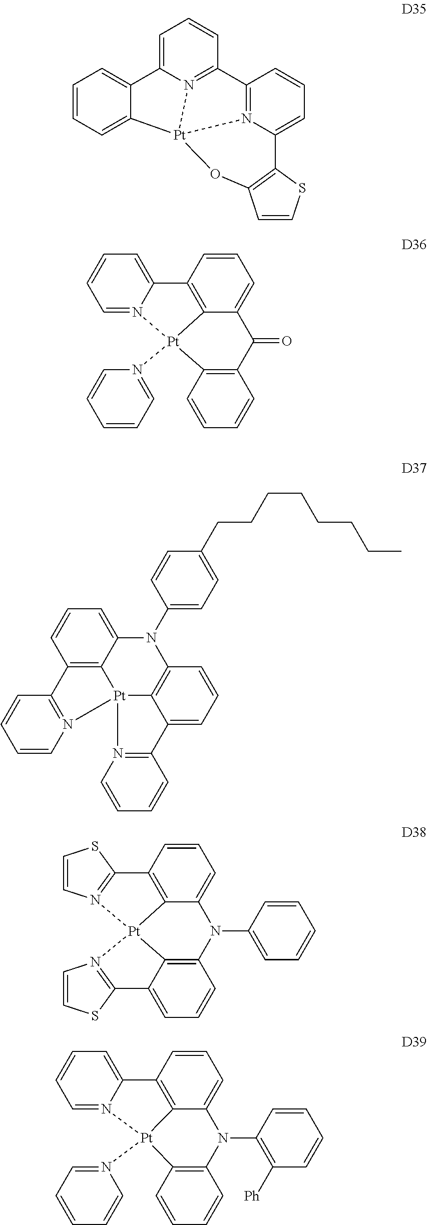

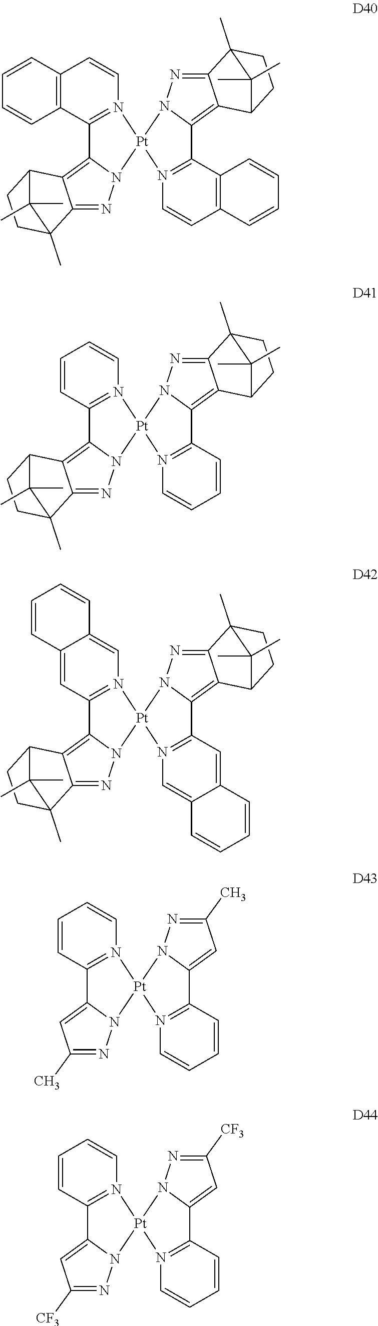

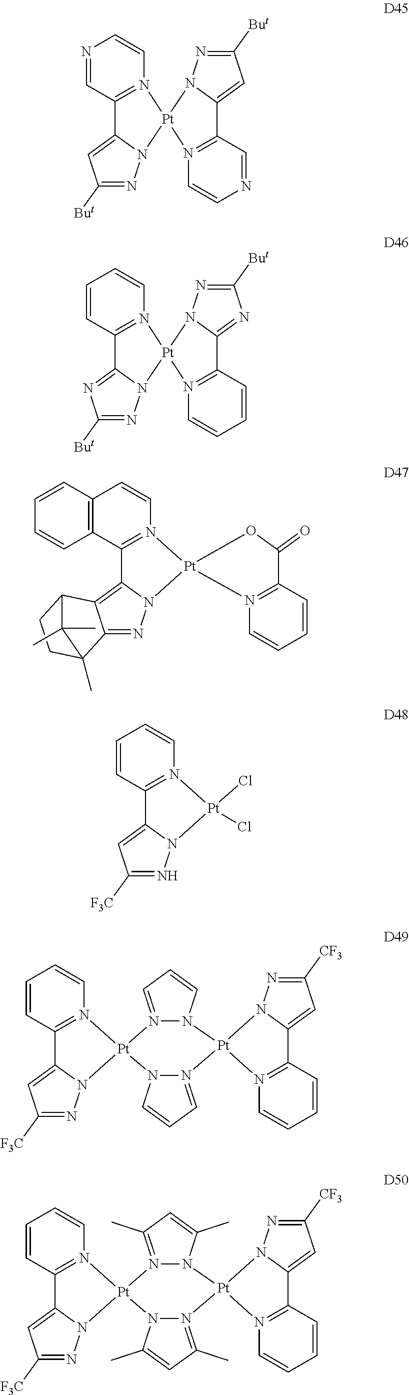

Also, the dopant that may be included in the EML may be an Os-complex described below, but is not limited thereto:

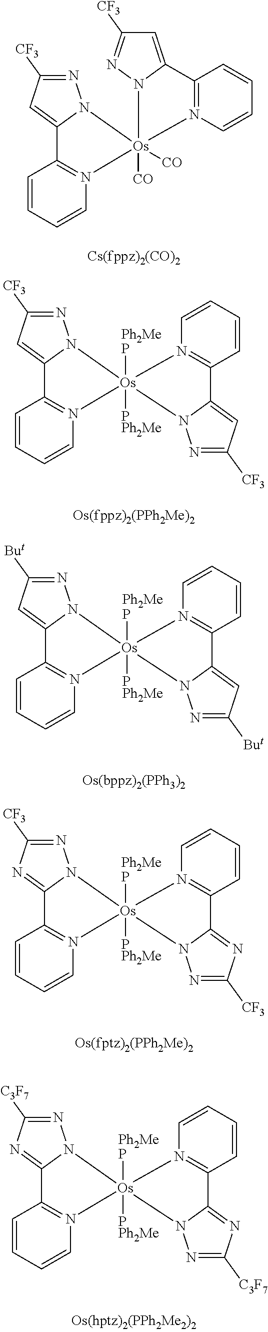

When the EML includes both a host and a dopant, the amount of the dopant may be from about 0.01 parts by weight to about 15 parts by weight based on 100 parts by weight of the host. However, the amount of the dopant is not limited to this range.

The thickness of the EML may be about 100 Å to about 1000 Å, and in some embodiments, is from about 200 Å to about 600 Å. In one embodiment, when the thickness of the EML is within these ranges, the EML has good light emitting ability without a substantial increase in the driving voltage.

Then, ETL is formed on the EML by using various methods such as vacuum deposition, spin coating, and casting. When the ETL is formed by using vacuum deposition or spin coating, the conditions for deposition and coating may be similar to those for the formation of the HIL, although the conditions for deposition and coating may vary according to the material that is used to form the ETL. The anthracene-based compound represented by Formula 1 above may be used as a material for the ETL.

A thickness of the ETL may be about 100 Å to about 1000 Å, and in some embodiments, is from about 150 Å to about 500 Å. In one embodiment, when the thickness of the ETL is within these ranges, the ETL has improved electron transport ability without a substantial increase in the driving voltage.

The ETL may further include a metal-containing material in addition to the anthracene-based compound described above.

The metal-containing material may include lithium (Li) complex. Non-limiting examples of the Li complex are lithium quinolate (LiQ) and Compound 203 below:

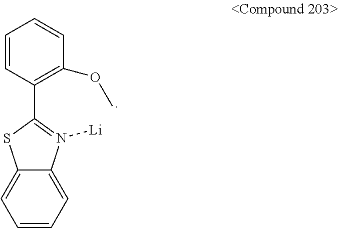

Then, an EIL, which facilitates injection of electrons from the cathode, may be formed on the ETL. Any suitable electron-injecting material may be used to form the EIL.

Non-limiting examples of the material for forming the EIL are LiF, NaCl, CsF, Li₂O, and BaO. The deposition and coating conditions for forming the EIL may be similar to those for the formation of the HIL, though the deposition and coating conditions may vary according to the material that is used to form the EIL.

A thickness of the EIL may be from about 1 Å to about 100 Å, and in some embodiments, is from about 3 Å to about 90 Å. In one embodiment, when the thickness of the EIL is within these ranges, the EIL has satisfactory electron injection ability without a substantial increase in the driving voltage.

The second electrode 17 is disposed on the organic layer 15. The second electrode 17 may be a cathode that is an electron injection electrode. A material for forming the second electrode 17 may be a metal, an alloy, an electro-conductive compound, which have a low work function, or a mixture thereof. In this regard, the second electrode 17 may be formed of lithium (Li), magnesium (Mg), aluminum (Al), aluminum-lithium (Al—Li), calcium (Ca), magnesium-indium (Mg—In), magnesium-silver (Mg—Ag), or the like, and may be formed as a thin film type transmission electrode. In some embodiments, to manufacture a top-emission light-emitting diode, the transmission electrode may be formed of indium tin oxide (ITO) or indium zinc oxide (IZO).

Although the organic light-emitting diode of FIG. 1 is described above, the present disclosure is not limited thereto.

When a phosphorescent dopant is also used in the EML, the HBL may be formed between the HTL and the EML or between the H-functional layer and the EML by using vacuum deposition, spin coating, casting, LB deposition, or the like, in order to prevent diffusion of triplet excitons or holes into an ETL. When the HBL is formed using vacuum deposition or spin coating, the conditions for deposition and coating may be similar to those for the formation of the HIL, although the conditions for deposition and coating may vary according to the material that is used to form the HBL. A suitable hole blocking material may be used, such as oxadiazole derivatives, triazole derivatives, or phenanthroline derivatives. For example, BCP as described below is used as the hole blocking material.

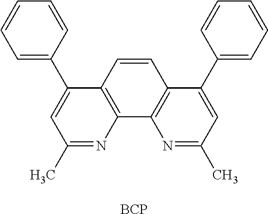 [SMILES: Cc1cc(-c2ccccc2)c2ccc3c(-c4ccccc4)cc(C)nc3c2n1 ; "BCP"]

A thickness of the HBL may be from about 20 Å to about 1000 Å, and in some embodiments, is from about 30 Å to about 300 Å. In one embodiment, when the thickness of the HBL is within these ranges, the HBL has improved hole blocking ability without a substantial increase in the driving voltage.

Examples of the unsubstituted C₁-C₆₀ alkyl group (or a C₁-C₆₀ alkyl group) used herein are linear or branched C₁-C₆₀ alkyl groups, such as methyl group, ethyl group, propyl group, isobutyl group, sec-butyl group, pentyl group, iso-amyl group, and hexyl group. At least one substituent of the substituted C₁-C₆₀ alkyl group may be selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, and a C₂-C₆₀ heteroaryl group;

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, and a C₂-C₆₀ heteroaryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, C₁-C₆₀ alkyl group, C₂-C₆₀ alkenyl group, C₂-C₆₀ alkynyl group, C₁-C₆₀ alkoxy group, a phenyl group, a naphthyl group, an anthryl group, a fluorenyl group, a dimethyl fluorenyl group, a diphenyl fluorenyl group, a carbazolyl group, a phenyl carbazolyl group, a pyridinyl group, a pyrimidinyl group, a pyrazinyl group, a pyridazinyl group, a triazinyl group, a quinolinyl group, and an isoquinolinyl group;

—N(Q₁₁)(Q₁₂); and —Si(Q₁₁)(Q₁₂)(Q₁₃) (here, Q₁₁ and Q₁₂ are, each independently, a C₆-C₆₀ aryl group, or a C₂-C₆₀ heteroaryl group, Q₁₃ to Q₁₅ are, each independently, a C₁-C₆₀ alkyl group, a C₁-C₆₀ alkoxy group, a C₆-C₆₀ aryl group, or a C₂-C₆₀ heteroaryl group), but is not limited thereto.

The unsubstituted C₁-C₆₀ alkoxy group (or C₁-C₆₀ alkoxy group) may be a group represented by —OA, wherein A is an unsubstituted C₁-C₆₀ alkyl group described above. Examples of the unsubstituted C₁-C₆₀ alkoxy group are a methoxy group, an ethoxy group, and an isopropyloxy group. At least one of the hydrogen atom in the alkoxy group may be substituted with those substituents described above in conjunction with the substituted C₁-C₆₀ alkyl group.

As used herein, the unsubstituted C₂-C₆₀ alkenyl group (or a C₂-C₆₀ alkenyl group) is a hydrocarbon chain having at least one carbon-carbon double bond in the center or at a terminal of the unsubstituted C₂-C₆₀ alkyl group. Examples of the alkenyl group are an ethenyl group, a propenyl group, a butenyl group, and the like. At least one hydrogen atom in the unsubstituted C₂-C₆₀ alkenyl group may be substituted with those substituents described above in conjunction with the substituted C₁-C₆₀ alkyl group.

The unsubstituted C₂-C₆₀ alkynyl group (or C₂-C₆₀ alkynyl group) is a C₂-C₆₀ alkyl group having at least one carbon-carbon triple bond in the center or at a terminal thereof. Examples of the unsubstituted C₂-C₆₀ alkynyl group are an ethenyl group, a propynyl group, and the like. At least one hydrogen atom in the alkynyl group may be substituted with those substituents described above in conjunction with the substituted C₁-C₆₀ alkyl group.

The unsubstituted C₆-C₆₀ aryl group is a monovalent group having a carbocyclic aromatic system having 6 to 60 carbon atoms including at least one aromatic ring. The unsubstituted C₆-C₆₀ arylene group is a divalent group having a carbocyclic aromatic system having 6 to 60 carbon atoms including at least one aromatic ring. When the aryl group and the arylene group have at least two rings, they may be fused to each other. At least one hydrogen atom in the aryl group and the arylene group may be substituted with those substituents described above in conjunction with the C₁-C₆₀ alkyl group.

Examples of the substituted or unsubstituted C₆-C₆₀ aryl group are a phenyl group, a C₁-C₁₀ alkylphenyl group (e.g., an ethylphenyl group), a C₁-C₁₀ alkylbiphenyl group (e.g., an ethylbiphenyl group), a halophenyl group (e.g., an o-, m- or p-fluorophenyl group and a dichlorophenyl group), a dicyanophenyl group, a trifluoromethoxyphenyl group, an o-, m- or p-tolyl group, an o-, m- or p-cumenyl group, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (e.g., a fluoronaphthyl group), a C₁-C₁₀ alkylnaphthyl group (e.g., a methylnaphthyl group), a C₁-C₁₀ alkoxynaphthyl group (e.g., a methoxynaphthyl group), an anthracenyl group, an azulenyl group, a heptalenyl group, an acenaphthylenyl group, a phenalenyl group, a fluorenyl group, an anthraquinolinyl group, a methylanthryl group, a phenanthryl group, a triphenylenyl group, a pyrenyl group, a chrysenyl group, an ethyl-chrysenyl group, a picenyl group, a perylenyl group, a chloroperylenyl group, a pentaphenyl group, a pentacenyl group, a tetraphenylenyl group, a hexaphenyl group, hexacenyl group, a rubicenyl group, a coronenyl group, a trinaphthylenyl group, a heptaphenyl group, a heptacenyl group, a pyranthrenyl group, and an ovalenyl group. Examples of the substituted C₆-C₆₀ aryl group may be inferred based on those of the unsubstituted C₆-C₆₀ aryl group and the substituted C₁-C₆₀ alkyl group described above. Examples of the substituted or unsubstituted C₆-C₆₀ arylene group may be inferred based on those examples of the substituted or unsubstituted C₆-C₆₀ aryl group described above.

The unsubstituted C₂-C₆₀ heteroaryl group is a monovalent group having at least one aromatic ring having at least one of the heteroatoms selected from the group consisting of N, O, P, and S. The unsubstituted C₂-C₆₀ heteroarylene group is a divalent group having at least one aromatic ring having at least one of the heteroatoms selected from the group consisting of N, O, P, and S. In this regard, when the heteroaryl group and the heteroarylene group have at least two rings, they may be fused to each other via a single bond. At least one hydrogen atom in the heteroaryl group and the heteroarylene group may be substituted with those substituents described with reference to the C₁-C₆₀ alkyl group.

Examples of the unsubstituted C₂-C₆₀ heteroaryl group are a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, a benzoimidazolyl group, an imidazopyridinyl group, an imidazopyrimidinyl group, or the like. The examples of the unsubstituted C₂-C₅₀ heteroarylene group may be inferred based on those examples of the substituted or unsubstituted C₂-C₆₀ arylene group.

The substituted or unsubstituted C₆-C₆₀ aryloxy group indicates —OA₂ (where A₂ is a substituted or unsubstituted C₆-C₆₀ aryl group described above). The substituted or unsubstituted C₅-C₆₀ arylthio group indicates —SA₃ (where A₃ is a substituted or unsubstituted C₆-C₆₀ aryl group described above).

Hereinafter, the organic light emitting diode according to an embodiment of the present disclosure will be described in more detail with reference to the following synthesis examples and other examples. However, these examples are for illustrative purposes only and are not intended to limit the scope of the present disclosure.

### EXAMPLES

### Synthesis Example 1

### Synthesis of Compound 1

Compound 1 was synthesized according to Reaction Scheme 1 below:

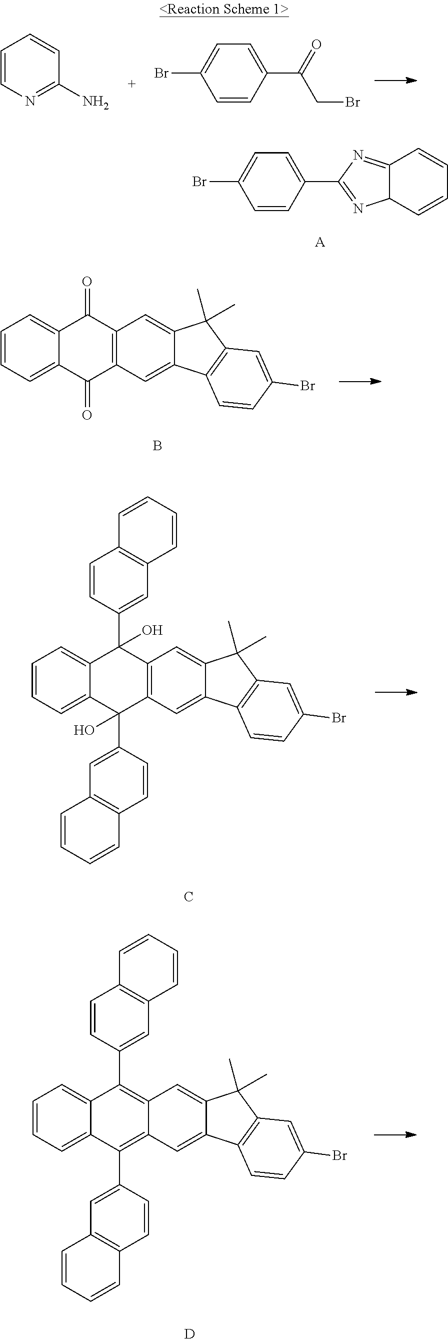

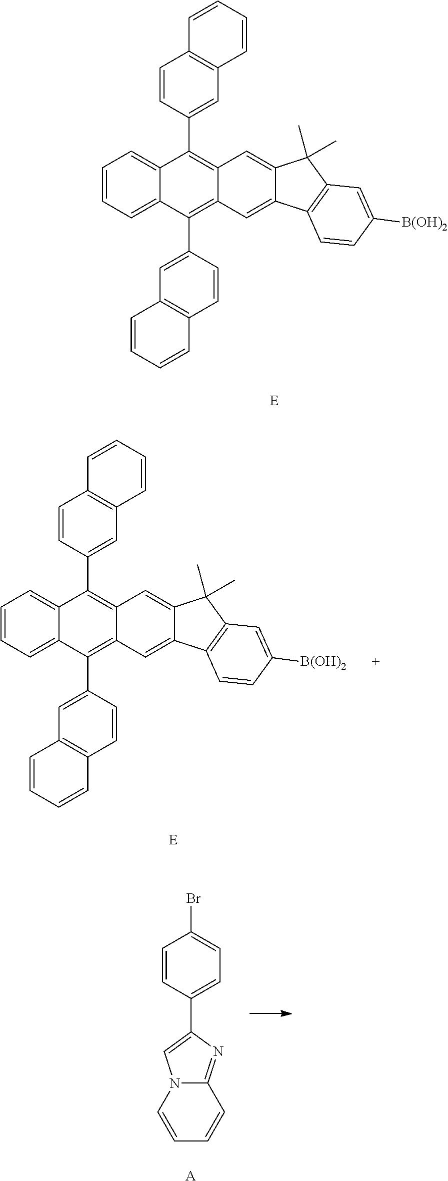

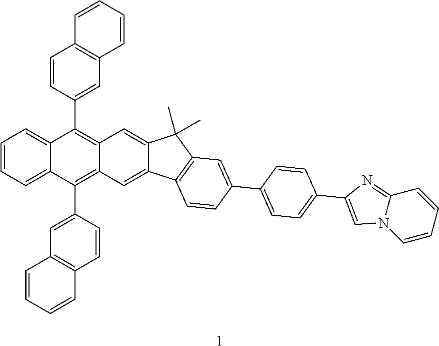 [SMILES: CC1(C)c2cc(-c3ccc(-c4cn5ccccc5n4)cc3)ccc2-c2cc3c(-c4ccc5ccccc5c4)c4ccccc4c(-c4ccc5ccccc5c4)c3cc21 ; "1"]

### Synthesis of Intermediate A

3.39 g of 2-aminopyridine and 10 g of 2,4-dibromoacetophenone were dissolved in 150 ml of ethanol and then refluxed for 12 hours to prepare a mixture. A white solid obtained by cooling the mixture at room temperature was washed with NaHCO₃ saturated aqueous solution, and recrystallized by using dichloromethane/hexane solution to obtain 8.02 g (yield rate of 82%) of an intermediate A.

### Synthesis of Intermediate C

A starting material B was added to 100 ml of THF that was dried in a N₂ atmosphere, then, temperature was decreased to −78° C., and slowly added 2-naphthyl magnesium bromide (0.5 M, 10 mmol) thereto to obtain a reaction mixture. Then, temperature was increased to room temperature and the reaction mixture was stirred for three hours. Ammonium chloride aqueous solution was added to the reaction mixture and then methylene chloride was used to extract the reaction mixture. An organic layer was dried by using anhydrous magnesium sulfate and the solvent was removed. A small amount of ethyl ether was used to dissolve the reaction mixture, then, petroleum ether was added thereto, and the reaction mixture was stirred for few hours to obtain a solid compound. The solid compound was filtered and vacuum dried to obtain a dinaphthyl alcohol Intermediate C.

### Synthesis of Intermediate D

21.3 g (32.4 mmol) of the intermediate C was dispersed in acetic acid in a N₂ atmosphere, then, 53.4 g (330 mmol) potassium iodide and 58 g (660 mmol) sodium hypophosphate hydrate were added thereto to obtain a reaction mixture, followed by an agitation and reflux of the reaction mixture for three hours. The reaction mixture was cooled to room temperature, filtered, washed with water and methanol, and then vacuum dried to obtain 17 g of an Intermediate D.

### Synthesis of Intermediate E

17 g (27.2 mmol) of the Intermediate D was dissolved in THF, and 14.5 ml (32.6 mmol) of butyl lithium was slowly added dropwise at −78° C., and after one hour, 3.2 ml (42.3 mmol) of trimethyl borate was added thereto to obtain a reaction mixture. The temperature was increased to room temperature, and one hour after the temperature was increased, 2N hydrochloric acid was added to the reaction mixture and stirred the reaction mixture for 3 hours to obtain a solid compound. The solid compound was washed with toluene while filtering the same to obtain 13.6 g of an Intermediate E.

### Synthesis of Compound 1

6.3 g (23.1 mmol) of the Intermediate A and 13.6 g (23.1 mmol) of Intermediate E were added to a solvent mixture of 17 g (115.5 mmol) of potassium carbonate aqueous solution and THF, added 1.4 g (1.16 mmol) of Pd(PPh₃)₄ thereto while stirring the same, and then refluxed the same for 8 hours. After cooling the solid compound to room temperature, the solid compound was filtered while being washed with water, ethanol, and THF to obtain 12.6 g (yield rate of 74%) of Compound 1.

1H NMR (300 MHz, CDCl₃) 8.37-8.33 (2H), 8.30 (2H), 8.15-8.10 (2H), 8.03 (4H), 7.95-7.91 (4H), 7.86-7.82 (3H), 7.75-7.70 (4H), 7.63-7.57 (6H), 7.47 (1H), 7.36 (2H), 7.24 (1H), 6.91 (1H), 1.75 (6H).

### Synthesis Example 2

### Synthesis of Compound 7

Compound 7 was synthesized according to Reaction Scheme 2 below:

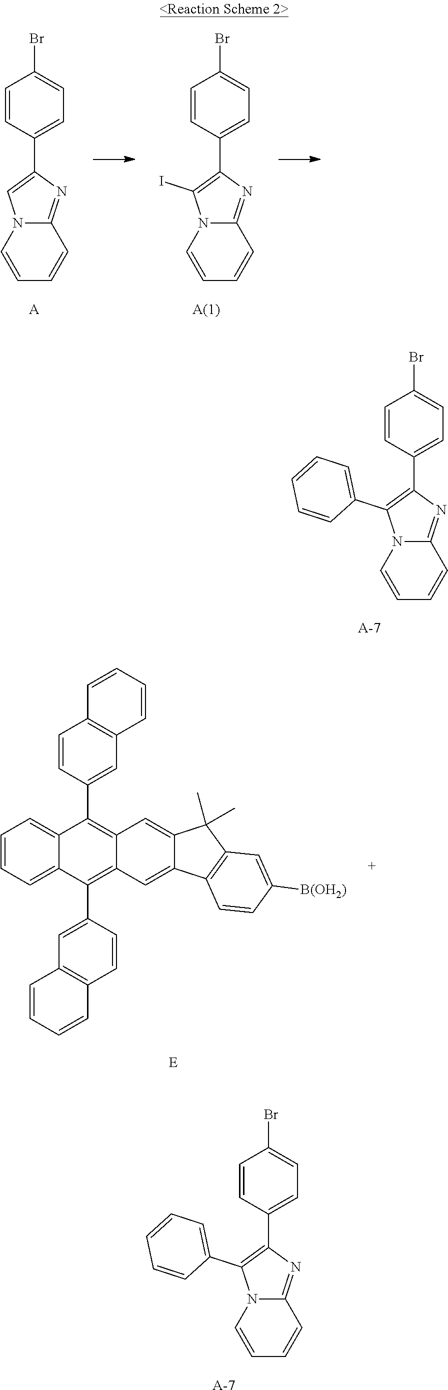

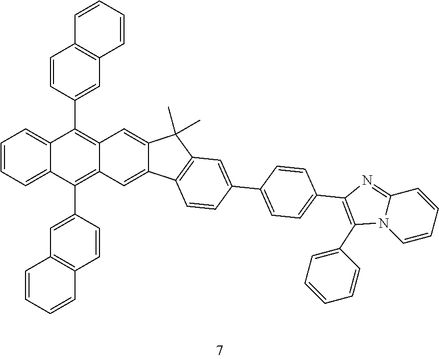 [SMILES: CC1(C)c2cc(-c3ccc(-c4nc5ccccn5c4-c4ccccc4)cc3)ccc2-c2cc3c(-c4ccc5ccccc5c4)c4ccccc4c(-c4ccc5ccccc5c4)c3cc21]

### Synthesis of Intermediate A(1)

5 g (18.3 mmol) of Intermediate A and 4.12 g (18.3 mmol) of NIS (N-iodized succinic acid) were dissolved in acetonitrile solvent, stirred for 1 hour at room temperature, added 100 ml of chloroform thereto, washed with 10% of sodium hydroxide aqueous solution, then washed with saturated sodium thiosulfate aqueous solution and water, dried with anhydrous magnesium sulfate, and then filtered the same, followed by a removal of the solvent to obtain a solid. The solid was washed with methanol and then filtered to obtain 5.8 g (yield rate of 79%) of an Intermediate A(1).

### Synthesis of Intermediate A-7

Intermediate A(1) and 1.76 g (14.5 mmol) of phenyl boronic acid were added to a solvent mixture of 10 g of potassium carbonate aqueous solution and THF, added 335 mg of Pd(PPh₃)₄ while stirring the same, and then refluxed for 24 hours to obtain a reaction mixture solution.

The reaction mixture solution was extracted by using dichloromethane, then, residual moisture in the organic layer was removed by using anhydrous magnesium sulfate, dried the same by applying a reduced pressure, and separated the same by using a column chromatography (ethyl acetate: normal hexane) to obtain 2.93 g (yield rate of 58%) of Intermediate A-7.

### Synthesis of Compound 7

Compound 7 (yield rate of 72%) was synthesized in the same manner as in the synthesis of Compound 1 in Synthesis Example 1 above, except for using Intermediate A-7 instead of Intermediate A.

1H NMR (300 MHz, CDCl₃) 8.39-8.33 (3H), 8.13-8.08 (2H), 8.01 (4H), 7.96-7.91 (4H), 7.89-7.83 (3H), 7.79-7.70 (4H), 7.62-7.53 (10H), 7.47-7.38 (4H), 7.24 (1H), 6.91 (1H), 1.75 (6H).

### Synthesis Example 3

### Synthesis of Compound 13

Compound 13 was synthesized according to Reaction Scheme 3 below:

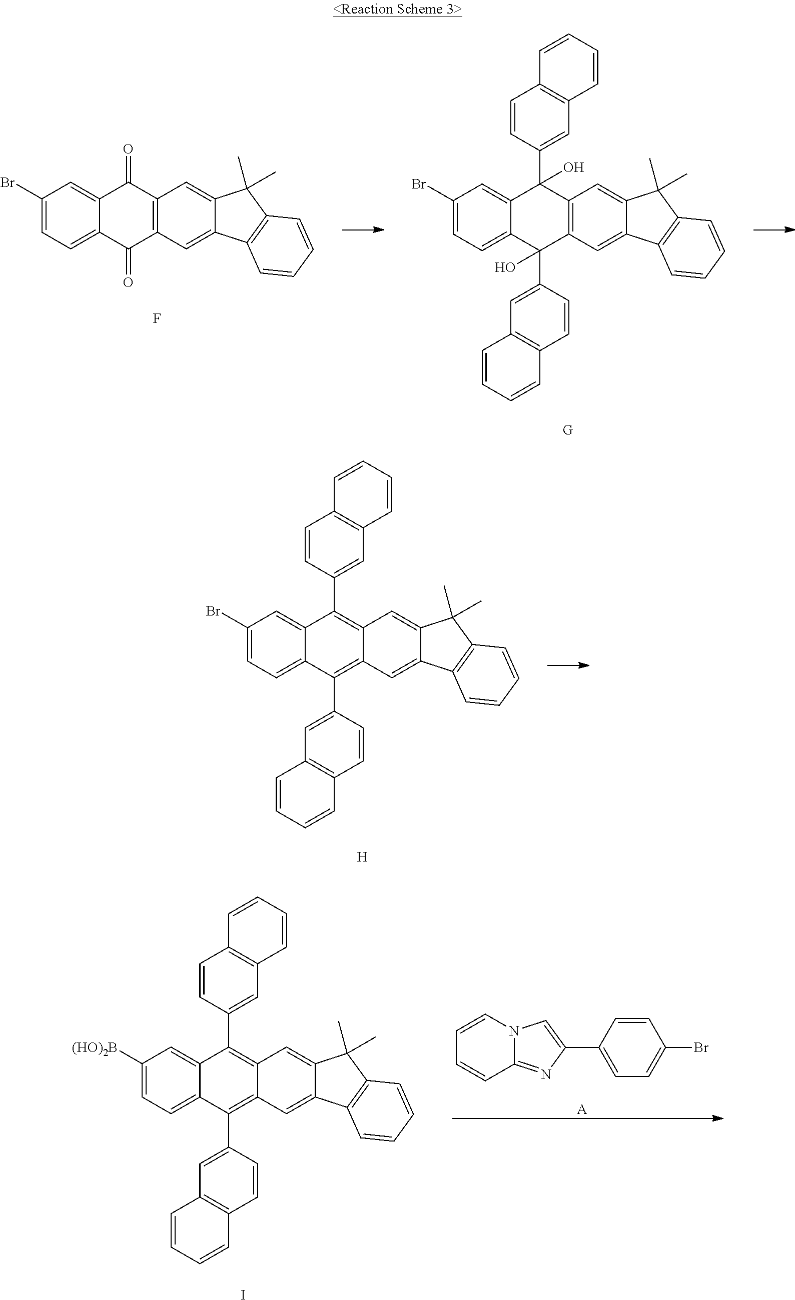

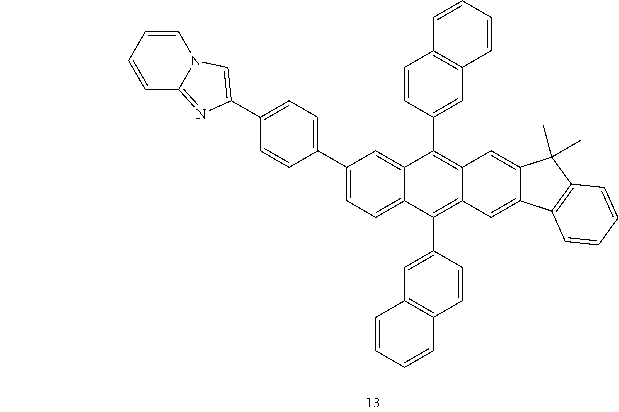 [SMILES: CC1(C)c2ccccc2-c2cc3c(-c4ccc5ccccc5c4)c4ccc(-c5ccc(-c6cn7ccccc7n6)cc5)cc4c(-c4ccc5ccccc5c4)c3cc21]

### Synthesis of Intermediate G

Intermediate G was synthesized in the same manner as in the synthesis of Intermediate C in Synthesis Example 1, except for using a starting material F instead of the starting material B.

### Synthesis of Intermediate H

Intermediate H was synthesized in the same manner as in the synthesis of Intermediate D in Synthesis Example 1, except for using a starting material G instead of the starting material C.

### Synthesis of Intermediate I

Intermediate I was synthesized in the same manner as in the synthesis of Intermediate E in Synthesis Example 1, except for using a starting material H instead of the starting material D.

### Synthesis of Compound 13

Compound 13 (yield rate of 78%) was synthesized in the same manner as in the synthesis of Compound 1 in Synthesis Example 1, except for using a starting material I instead of the starting material E.

1H NMR (300 MHz, CDCl₃) 8.41 (1H), 8.37-8.32 (3H), 8.13 (1H), 8.08-8.02 (3H), 7.97-7.91 (3H), 7.84 (2H), 7.76-7.71 (7H), 7.63-7.58 (2H), 7.53-7.48 (6H), 7.38-7.24 (4H), 1.75 (6H).

### Synthesis Example 4

### Synthesis of Compound 19

Compound 19 was synthesized according to Reaction Scheme 4 below:

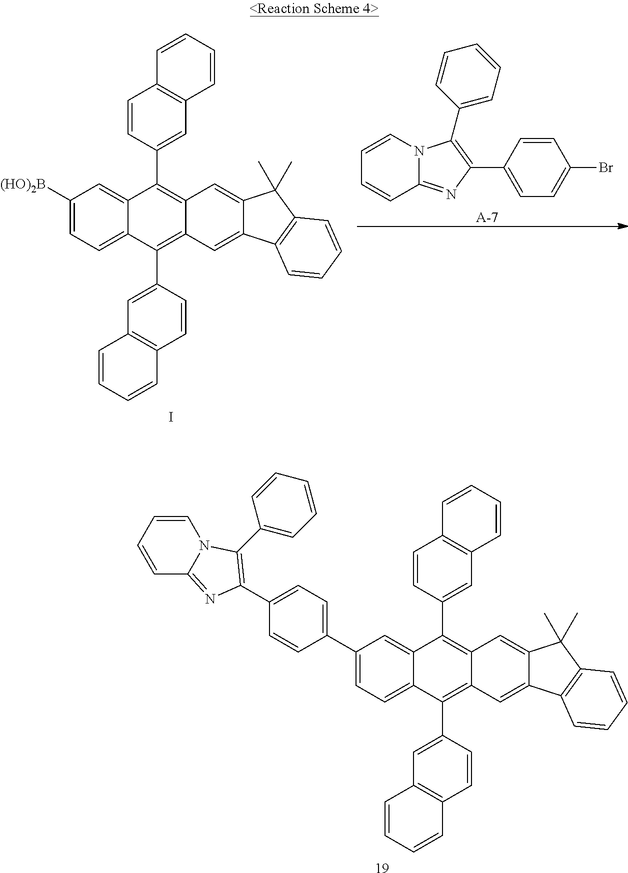

Compound 19 (yield rate of 67%) was synthesized in the same manner as in the synthesis of Compound 1 in Synthesis Example 1, except for using Intermediates I and A-7 instead of Intermediates E and A, respectively.

1H NMR (300 MHz, CDCl₃) 8.38 (1H), 8.29 (2H), 8.18-8.02 (6H), 7.96-7.87 (5H), 7.82-7.74 (5H), 7.68-7.54 (9H), 7.56-7.43 (4H), 7.38-7.21 (4H), 1.75 (6H).

### Example 1

As an anode, a Corning 15 Ω/cm² ITO glass substrate was cut into a size of 50 mm×50 mm×0.7 mm, and each ITO glass substrate was ultrasonically washed using isopropyl alcohol and distilled water for 5 minutes, followed by UV ozone cleaning for about 30 minutes. The ITO glass substrate was then loaded onto a vacuum deposition device to form an ITO layer.

2-TNATA was deposited on the ITO layer (anode) to form a hole injection layer having a thickness of 600 Å, and NPB was deposited on the hole injection layer to form a hole transport layer having a thickness of 300 Å.

Then, 9,10-di-naphthalene-2-yl-anthracene (AND, a host) and BPAVBi (4,4′-Bis[4-(diphenylamino)styryl]biphenyl, a dopant) were vacuum deposited in a weight ratio of 97:3, respectively, to form an emission layer having a thickness of 300 Å.

Thereafter, Compound 1 was deposited on the emission layer to form an electron transport layer having a thickness of 300 Å, and LiF was deposited on the electron transport layer to form a hole injection layer having a thickness of 10 Å, and Al was deposited on the electron injection layer to form a second electrode (cathode) having a thickness of 3000 Å, thereby manufacturing an organic light emitting diode,

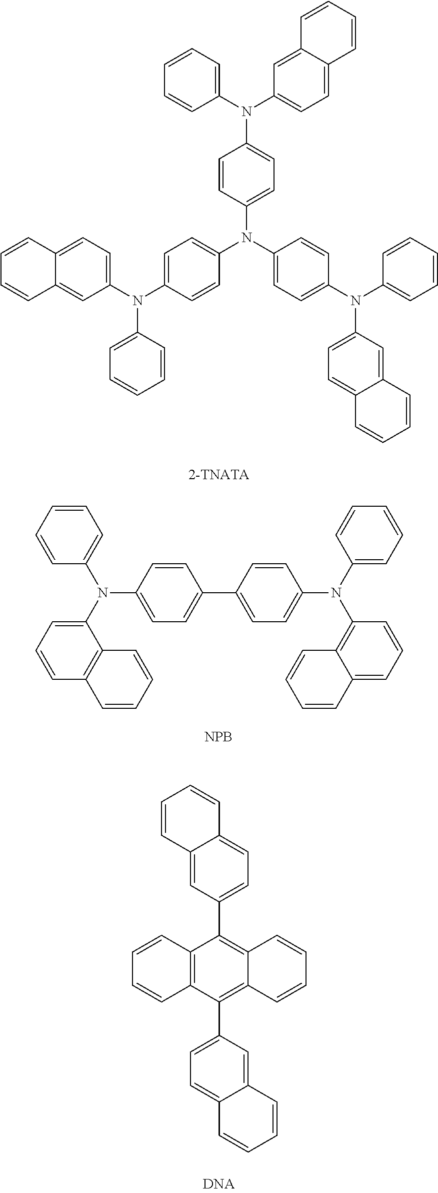

### Example 2

An organic light emitting diode was manufactured in the same manner as in Example 1, except for using Compound 7 instead of Compound 1 when forming an electron transport layer.

### Example 3

An organic light emitting diode was manufactured in the same manner as in Example 1, except for using Compound 13 instead of Compound 1 when forming an electron transport layer.

### Example 4

An organic light emitting diode was manufactured in the same manner as in Example 1, except for using Compound 19 instead of Compound 1 when forming an electron transport layer.

### Comparative Example 1

An organic light emitting diode was manufactured in the same manner as in Example 1, except for using Alq₃ instead of Compound 1 when forming an electron transport layer.

### Comparative Example 2

An organic light emitting diode was manufactured in the same manner as in Example 1, except for using Compound A instead of Compound 1 when forming an electron transport layer.

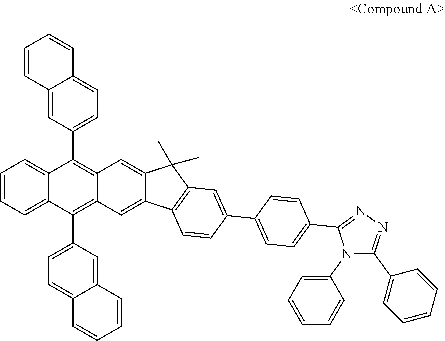 [SMILES: CC1(C)c2cc(-c3ccc(-c4nnc(-c5ccccc5)n4-c4ccccc4)cc3)ccc2-c2cc3c(-c4ccc5ccccc5c4)c4ccccc4c(-c4ccc5ccccc5c4)c3cc21]

### Comparative Example 3

An organic light emitting diode was manufactured in the same manner as in Example 1, except for using Compound B instead of Compound 1 when forming an electron transport layer.

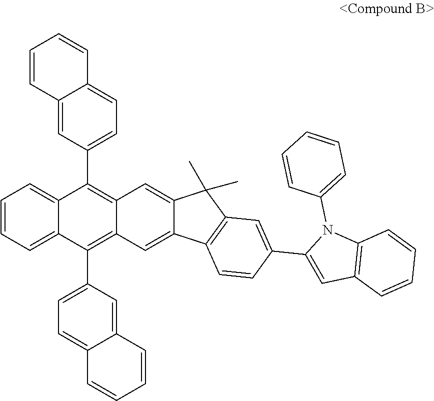 [SMILES: CC1(C)c2cc(-c3cc4ccccc4n3-c3ccccc3)ccc2-c2cc3c(-c4ccc5ccccc5c4)c4ccccc4c(-c4ccc5ccccc5c4)c3cc21]

### Comparative Example 4

An organic light emitting diode was manufactured in the same manner as in Example 1, except for using Compound C instead of Compound 1 when forming an electron transport layer.

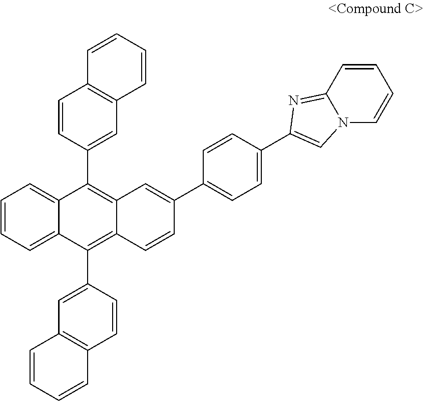 [SMILES: c1ccc2cc(-c3c4ccccc4c(-c4ccc5ccccc5c4)c4cc(-c5ccc(-c6cn7ccccc7n6)cc5)ccc34)ccc2c1]

### Comparative Example 5

An organic light emitting diode was manufactured in the same manner as in Example 1, except for using Compound D instead of Compound 1 when forming an electron transport layer.

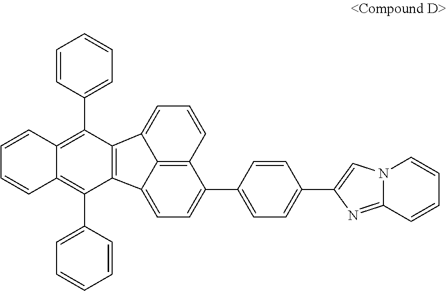 [SMILES: c1ccc(-c2c3c(c(-c4ccccc4)c4ccccc24)-c2ccc(-c4ccc(-c5cn6ccccc6n5)cc4)c4cccc-3c24)cc1]

### Comparative Example 6

An organic light emitting diode was manufactured in the same manner as in Example 1, except for using Compound E instead of Compound 1 when forming an electron transport layer.

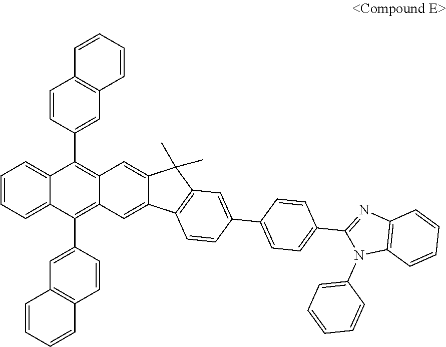 [SMILES: CC1(C)c2cc(-c3ccc(-c4nc5ccccc5n4-c4ccccc4)cc3)ccc2-c2cc3c(-c4ccc5ccccc5c4)c4ccccc4c(-c4ccc5ccccc5c4)c3cc21]

### Evaluation Example 1

Driving voltages and emission efficiency of the organic light emitting diodes of Examples 1 to 4 and Comparative Examples 1 to 6 were evaluated by using PR650 Spectroscan Source Measurement Unit (available from PhotoResearch). The results are shown in Tables 1 and 2:

TABLE 1

| | | | Emission |
|---|---|---|---|
| | Electron | Driving | efficiency |
| | transport | voltage | (cd/A) |
| | layer | (V) | @ 400 nit |
| Example 1 | Compound 1 | 4.4 | 3.77 |
| Example 2 | Compound 7 | 4.2 | 3.64 |
| Example 3 | Compound 13 | 4.2 | 3.42 |
| Example 4 | Compound 19 | 4.3 | 3.59 |
| Comparative | Alq₃ | 4.7 | 2.73 |
| Example 1 | | | |
| Comparative | Compound A | 7.1 | 2.84 |
| Example 2 | | | |
| Comparative | Compound B | 8.4 | 1.42 |
| Example 3 | | | |
| Comparative | Compound C | 4.4 | 3.03 |
| Example 4 | | | |
| Comparative | Compound D | 4.9 | 2.47 |
| Example 5 | | | |
| Comparative | Compound E | 5.2 | 2.29 |
| Example 6 | | | |

Referring to Tables 1 and 2, the organic light emitting diodes of Examples 1 to 4 are found to have lower driving voltages and higher emission efficiencies as compared with the organic light emitting diodes of Comparative Examples 1 to 6.

In view of the foregoing and according to embodiments of the present disclosure, an organic light emitting diode including the anthracene-based compound has a low driving voltage, a higher luminance, and a long lifespan.

While the present disclosure has been particularly shown and described with reference to exemplary embodiments thereof, it will be understood by those of ordinary skill in the art that various changes in form and details may be made therein without departing from the spirit and scope of the present disclosure as defined by the following claims and equivalents thereof.

What is claimed is:

1. An anthracene-based compound represented by Formula 1 below: 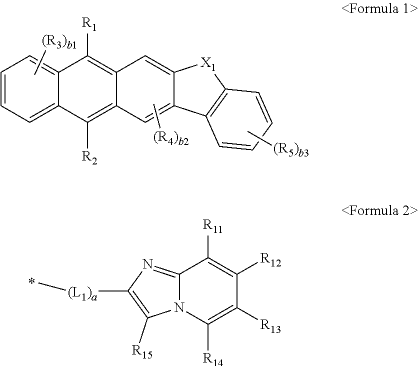
in Formulae 1 and 2,
X₁ is C(R₆)(R₇) or N(R₈);
R₁ to R₈ and R₁₁ to R₁₅ are, each independently, selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, —N(Q₁)(Q₂), —Si(Q₃)(Q₄)(Q₅), wherein, Q₁ to Q₅ are, each independently, a hydrogen atom, a substituted or unsubstituted C₁-C₆₀ alkyl group, a substituted or unsubstituted C₆-C₆₀ aryl group, or a substituted or unsubstituted C₂-C₆₀ heteroaryl group, and a group represented by Formula 2 above, wherein at least one of R₁, R₂, b1 number of R₃, b2 number of R₄ and b3 number of R₅ is a group represented by Formula 2 above;
b₁ and b₃ are, each independently, an integer of 1 to 4;
b₂ is 1 or 2;
L₁ is selected from a substituted or unsubstituted C₃-C₁₀ cycloalkylene group, a substituted or unsubstituted C₂-C₁₀ heterocycloalkylene group, a substituted or unsubstituted C₃-C₁₀ cycloalkenylene group, a substituted or unsubstituted C₂-C₁₀ heterocycloalkenylene group, a substituted or unsubstituted C₆-C₆₀ arylene group, and a substituted or unsubstituted C₂-C₆₃ heteroarylene group;
a is an integer of 0 to 5; and
* in Formula 2 is a binding site to a group represented by Formula 1.

2. The anthracene-based compound of claim 1, wherein X₁ is C(R₆)(R₇).

3. The anthracene-based compound of claim 1, wherein
R₆ to R₈ are, each independently, selected from,
a methyl group, an ethyl group, a propyl group, a butyl group, a pentyl group, a hexyl group, a heptyl group, and an octyl group;
a methyl group, an ethyl group, a propyl group, a butyl group, a pentyl group, a hexyl group, a heptyl group, and an octyl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a phenyl group, a naphthyl group, an anthryl group, and a dimethyl fluorenyl group;
a phenyl group, a naphthyl group, and an anthryl group; and
a phenyl group, a naphthyl group, and an anthryl group, each substituted with at least one of a deuterium atom, a halogen atom, a hydroxyl group, a cyano group, a nitro group, an amino group, an amidino group, a hydrazine, a hydrazone, a carboxyl group or a salt thereof, C₁-C₂₀ alkyl group, C₁-C₂₀ alkoxy group, a sulfonic acid group or a salt thereof, a phosphoric acid group or a salt thereof, a phenyl group, a naphthyl group, an anthryl group, and a dimethyl fluorenyl group.

4. The anthracene-based compound of claim 1, wherein
R₁ and R₂ are, each independently, selected from,
a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthryl group, a fluoranthenyl group, a triphenylenylene group, a pyrenyl group, a chrysenyl group, a naphthacenyl group, a picenyl group, a perylenyl group, a pentaphenyl group and a hexacenyl group; and
a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthryl group, a fluoranthenyl group, a triphenylenylene group, a pyrenyl group, a chrysenyl group, a naphthacenyl group, a picenyl group, a perylenyl group, a pentaphenyl group and a hexacenyl group, each substituted with at least one of a deuterium atom, a halogen atom, a hydroxyl group, a cyano group, a nitro group, an amino group, an amidino group, a hydrazine, a hydrazone, a carboxyl group or a salt thereof, a C₁-C₂₀ alkyl group, a C₁-C₂₀ alkoxy group, a sulfonic acid group or a salt thereof, a phosphoric acid group or a salt thereof, a phenyl group, a naphthyl group, an anthryl group, and a dimethyl fluorenyl group.

5. The anthracene-based compound of claim 1, wherein
R₁ and R₂ are, each independently, selected from,
a phenyl group, a naphthyl group, a fluorenyl group, and a spiro-fluorenyl group; and
a phenyl group, a naphthyl group, a fluorenyl group, and a spiro-fluorenyl group, each substituted with at least one of a deuterium atom, a halogen atom, a hydroxyl group, a cyano group, a nitro group, an amino group, an amidino group, a hydrazine, a hydrazone, a carboxyl group or a salt thereof, a C₁-C₂₀ alkyl group, a C₁-C₂₀ alkoxy group, a sulfonic acid group or a salt thereof, a phosphoric acid group or a salt thereof, a phenyl group, a naphthyl group, an anthryl group, and a dimethyl fluorenyl group.

6. The anthracene-based compound of claim 1, wherein
in Formula 1, R₃ to R₅ are, each independently, selected from,
a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group;
a C₁-C₆₀ alkyl group, and a C₁-C₆₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;
a C₆-C₂₀ aryl group;
a C₆-C₂₀ aryl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, a C₁-C₆₀ alkyl group, a C₁-C₆₀ alkoxy group, a phenyl group, a naphthyl group, and an anthryl group; and
a group represented by Formula 2;
wherein, at least one of b1 number of R₃, b2 number of R₄, and b3 number of R₅ is a group represented by Formula 2 above.

7. The anthracene-based compound of claim 1, wherein
in Formula 1, R₃ to R₅ are, each independently, selected from,
a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group;
a C₁-C₆₀ alkyl group and a C₁-C₆₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;
a phenyl group, a naphthyl group, and an anthryl group;
a phenyl group, a naphthyl group, and an anthryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, a C₁-C₆₀ alkyl group, a C₁-C₆₀ alkoxy group, a phenyl group, a naphthyl group, and an anthryl group; and
a group represented by Formula 2 above;
wherein, at least one of b1 number of R₃, b2 number of R₄ and b3 number of R₅ is a group represented by Formula 2 above.

8. The anthracene-based compound of claim 1, wherein at least one of b1 number of R₃ is a group represented by Formula 2 above, or at least one of b3 number of R₅ is a group represented by Formula 2 above.

9. The anthracene-based compound of claim 1, wherein
in Formula 2, L₁ is selected from,
a phenylene group, a naphthylene group, and an anthrylene group; and
a phenylene group, a naphthylene group, and an anthrylene group each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group.

10. The anthracene-based compound of claim 1, wherein in Formula 2, a is 1 or 2.

11. The anthracene-based compound of claim 1, wherein
in Formula 2, R₁₁ to R₁₅ are, each independently, selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a propyl group, a butyl group, a pentyl group, a hexyl group, a heptyl group, an octyl group, a methoxy group, an ethoxy group, a propoxy group, a butoxy group, a pentoxy group, a phenyl group, a naphthyl group, an anthryl group, a dimethyl fluorenyl group, and a phenyl carbazolyl group.

12. The anthracene-based compound of claim 1, wherein the anthracene-based compound is represented by Formulae 1A or 1B below: 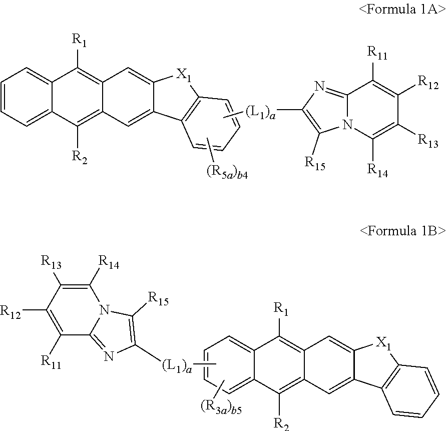
in Formulae 1A and 1B,
X₁ is C(R₆)(R₇) or N(R₈);
R₆ to R₈ are, each independently, selected from,
a methyl group, an ethyl group, a propyl group, a butyl group, a pentyl group, a hexyl group, a heptyl group, and an octyl group;
a methyl group, an ethyl group, a propyl group, a butyl group, a pentyl group, a hexyl group, a heptyl group, and an octyl group, each substituted with at least one substituent of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a phenyl group, a naphthyl group, an anthryl group, and a dimethyl fluorenyl group;
a phenyl group, a naphthyl group, and an anthryl group; and
a phenyl group, a naphthyl group, and an anthryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a C₁-C₂₀ alkyl group, a C₁-C₂₀ alkoxy group, a sulfonic acid group or a salt thereof, a phosphoric acid group or a salt thereof, a phenyl group, a naphthyl group, an anthryl group, and a dimethyl fluorenyl group;
R₁ and R₂ are, each independently, selected from,
a phenyl group, a naphthyl group, a fluorenyl group, and a spiro-fluorenyl group; and
a phenyl group, a naphthyl group, a fluorenyl group, and a spiro-fluorenyl group, each substituted with at least one of a deuterium atom, a halogen atom, a hydroxyl group, a cyano group, a nitro group, an amino group, an amidino group, a hydrazine, a hydrazone, a carboxyl group or a salt thereof, a C₁-C₂₀ alkyl group, a C₁-C₂₀ alkoxy group, a sulfonic acid group or a salt thereof, a phosphoric acid group or a salt thereof, a phenyl group, a naphthyl group, an anthryl group, and a dimethyl fluorenyl group;
R₅ₐ and R₃ₐ are, each independently,
a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group;
a C₁-C₆₀ alkyl group and a C₁-C₆₀ alkoxy group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;
a phenyl group, a naphthyl group, and an anthryl group; and
a phenyl group, a naphthyl group, and an anthryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof, a C₁-C₆₀ alkyl group, a C₁-C₆₀ alkoxy group, a phenyl group, a naphthyl group, and an anthryl group;
b4 and b5 are, each independently, an integer of 1 to 3;
L₁ is selected from
a phenylene group, a naphthylene group, and an anthrylene group; and
a phenylene group, a naphthylene group, and an anthrylene group each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group;
a is 1 or 2;
R₁₁ to R₁₅ are, each independently, selected from, a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a propyl group, a butyl group, a pentyl group, a hexyl group, a heptyl group, an octyl group, a methoxy group, an ethoxy group, a propoxy group, a butoxy group, a pentoxy group, a phenyl group, a naphthyl group, an anthryl group, a dimethyl fluorenyl group, and a phenyl carbazolyl group.

13. The anthracene-based compound of claim 12, wherein the anthracene-based compound is represented by Formula 1A(1) or Formula 1B(1) below: 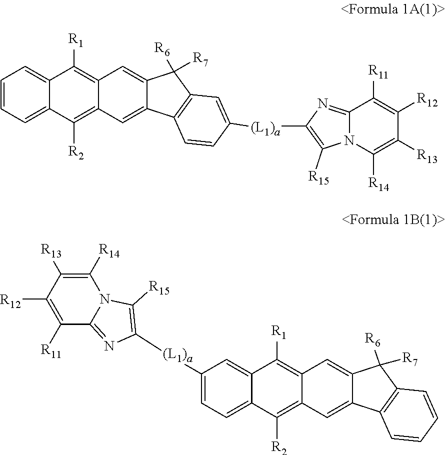
R₁, R₂, R₆, R₇, L₁, a and R₁₁ to R₁₅ of Formulae 1A(1) and 1B(1) are as described in claim 12.

14. The anthracene-based compound of claim 1, wherein the anthracene-based compound is one of Compounds 1 to 24 below:

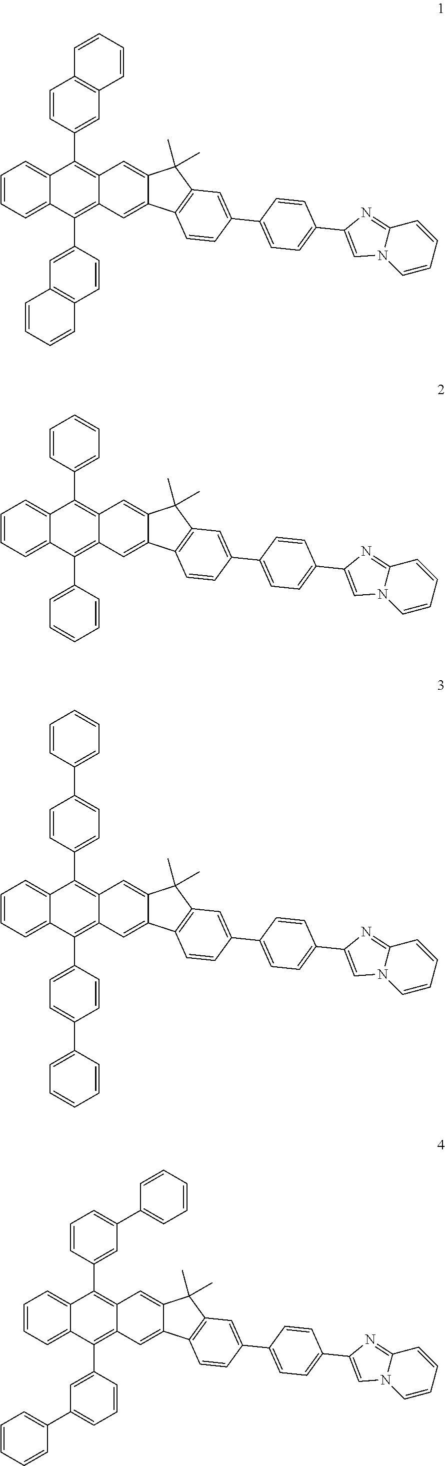 [SMILES: CC1(C)c2cc(-c3ccc(-c4cn5ccccc5n4)cc3)ccc2-c2cc3c(-c4ccc5ccccc5c4)c4ccccc4c(-c4ccc5ccccc5c4)c3cc21 ; CC1(C)c2cc(-c3ccc(-c4cn5ccccc5n4)cc3)ccc2-c2cc3c(-c4ccccc4)c4ccccc4c(-c4ccccc4)c3cc21 ; CC1(C)c2cc(-c3ccc(-c4cn5ccccc5n4)cc3)ccc2-c2cc3c(-c4ccc(-c5ccccc5)cc4)c4ccccc4c(-c4ccc(-c5ccccc5)cc4)c3cc21 ; CC1(C)c2cc(-c3ccc(-c4cn5ccccc5n4)cc3)ccc2-c2cc3c(-c4cccc(-c5ccccc5)c4)c4ccccc4c(-c4cccc(-c5ccccc5)c4)c3cc21]

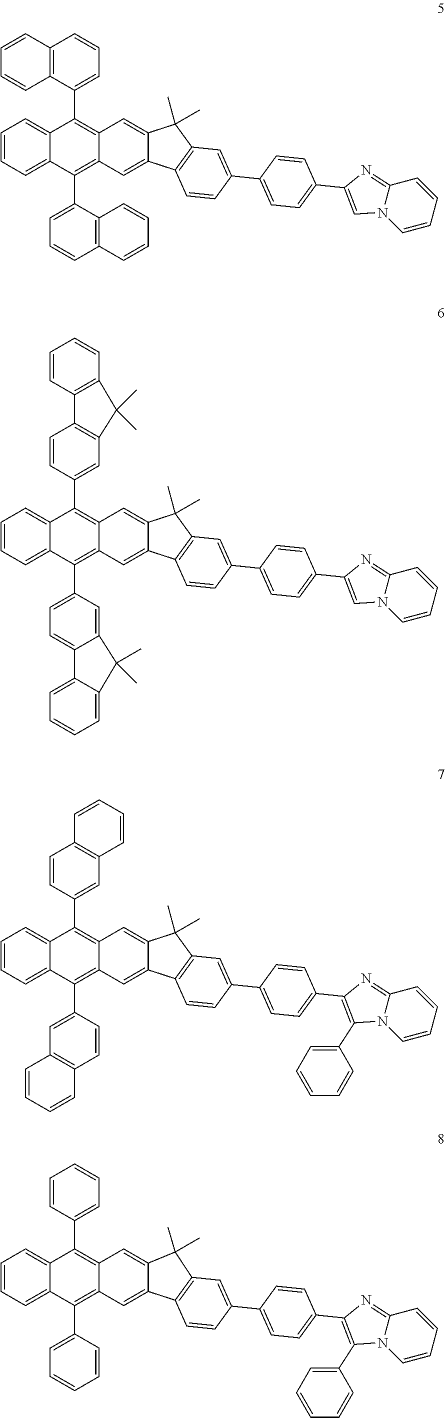 [SMILES: CC1(C)c2cc(-c3ccc(-c4cn5ccccc5n4)cc3)ccc2-c2cc3c(-c4cccc5ccccc45)c4ccccc4c(-c4cccc5ccccc45)c3cc21 ; CC1(C)c2ccccc2-c2ccc(-c3c4ccccc4c(-c4ccc5c(c4)C(C)(C)c4ccccc4-5)c4cc5c(cc34)-c3ccc(-c4ccc(-c6cn7ccccc7n6)cc4)cc3C5(C)C)cc21 ; CC1(C)c2cc(-c3ccc(-c4nc5ccccn5c4-c4ccccc4)cc3)ccc2-c2cc3c(-c4ccc5ccccc5c4)c4ccccc4c(-c4ccc5ccccc5c4)c3cc21 ; CC1(C)c2cc(-c3ccc(-c4nc5ccccn5c4-c4ccccc4)cc3)ccc2-c2cc3c(-c4ccccc4)c4ccccc4c(-c4ccccc4)c3cc21]

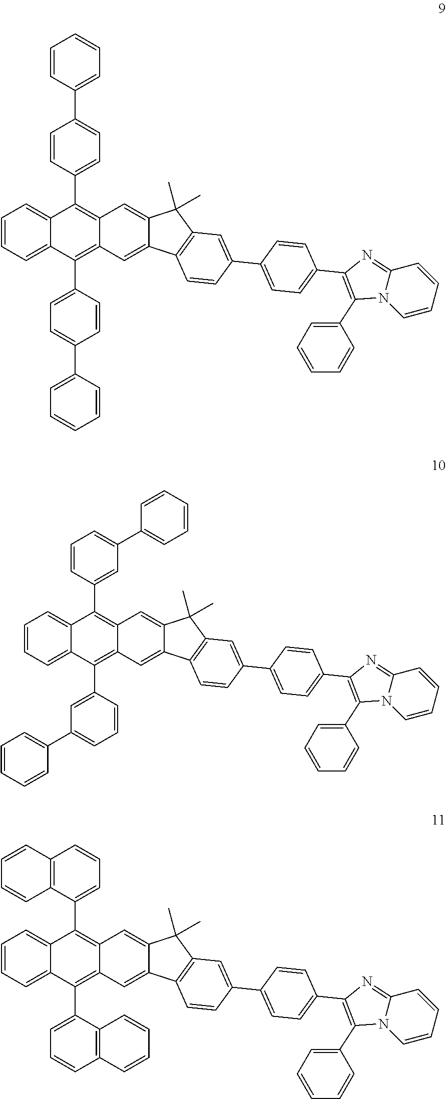 [SMILES: CC1(C)c2cc(-c3ccc(-c4nc5ccccn5c4-c4ccccc4)cc3)ccc2-c2cc3c(-c4ccc(-c5ccccc5)cc4)c4ccccc4c(-c4ccc(-c5ccccc5)cc4)c3cc21 ; CC1(C)c2cc(-c3ccc(-c4nc5ccccn5c4-c4ccccc4)cc3)ccc2-c2cc3c(-c4cccc(-c5ccccc5)c4)c4ccccc4c(-c4cccc(-c5ccccc5)c4)c3cc21 ; CC1(C)c2cc(-c3ccc(-c4nc5ccccn5c4-c4ccccc4)cc3)ccc2-c2cc3c(-c4cccc5ccccc45)c4ccccc4c(-c4cccc5ccccc45)c3cc21]

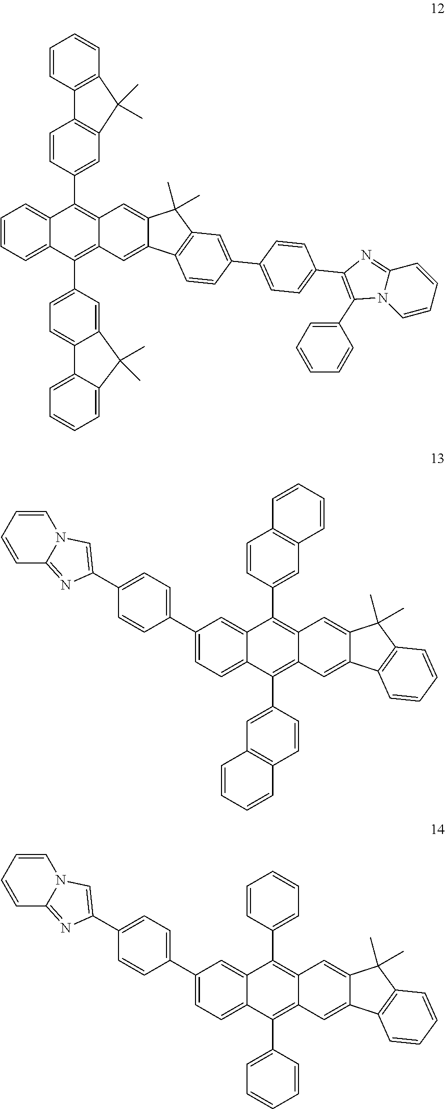 [SMILES: CC1(C)c2ccccc2-c2ccc(-c3c4ccccc4c(-c4ccc5c(c4)C(C)(C)c4ccccc4-5)c4cc5c(cc34)-c3ccc(-c4ccc(-c6nc7ccccn7c6-c6ccccc6)cc4)cc3C5(C)C)cc21 ; CC1(C)c2ccccc2-c2cc3c(-c4ccc5ccccc5c4)c4ccc(-c5ccc(-c6cn7ccccc7n6)cc5)cc4c(-c4ccc5ccccc5c4)c3cc21 ; CC1(C)c2ccccc2-c2cc3c(-c4ccccc4)c4ccc(-c5ccc(-c6cn7ccccc7n6)cc5)cc4c(-c4ccccc4)c3cc21]

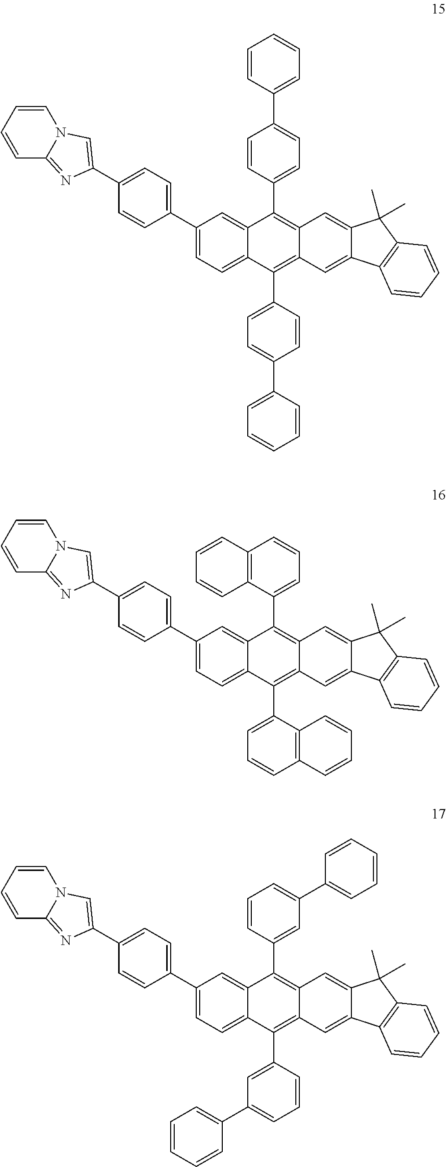 [SMILES: CC1(C)c2ccccc2-c2cc3c(-c4ccc(-c5ccccc5)cc4)c4ccc(-c5ccc(-c6cn7ccccc7n6)cc5)cc4c(-c4ccc(-c5ccccc5)cc4)c3cc21 ; CC1(C)c2ccccc2-c2cc3c(-c4cccc5ccccc45)c4ccc(-c5ccc(-c6cn7ccccc7n6)cc5)cc4c(-c4cccc5ccccc45)c3cc21 ; CC1(C)c2ccccc2-c2cc3c(-c4cccc(-c5ccccc5)c4)c4ccc(-c5ccc(-c6cn7ccccc7n6)cc5)cc4c(-c4cccc(-c5ccccc5)c4)c3cc21]

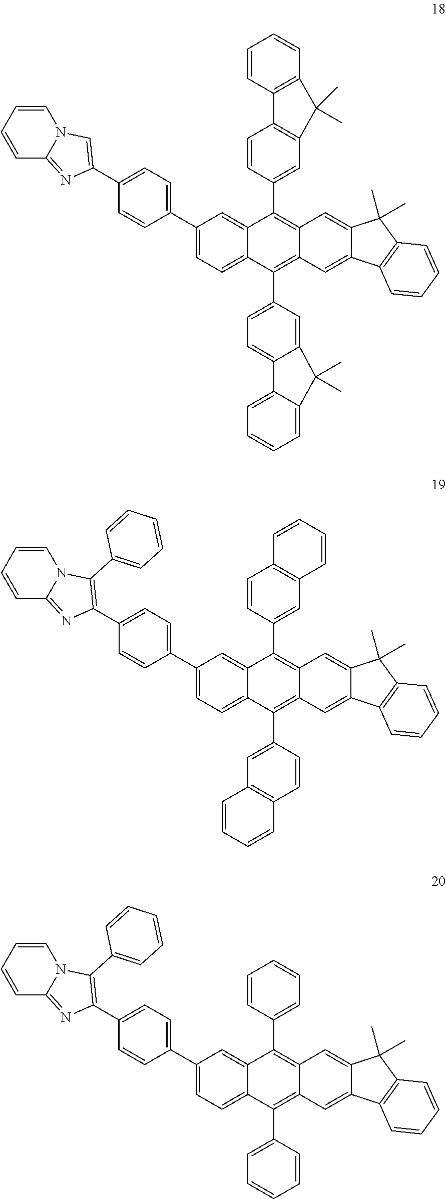 [SMILES: CC1(C)c2ccccc2-c2ccc(-c3c4ccc(-c5ccc(-c6cn7ccccc7n6)cc5)cc4c(-c4ccc5c(c4)C(C)(C)c4ccccc4-5)c4cc5c(cc34)-c3ccccc3C5(C)C)cc21 ; CC1(C)c2ccccc2-c2cc3c(-c4ccc5ccccc5c4)c4ccc(-c5ccc(-c6nc7ccccn7c6-c6ccccc6)cc5)cc4c(-c4ccc5ccccc5c4)c3cc21 ; CC1(C)c2ccccc2-c2cc3c(-c4ccccc4)c4ccc(-c5ccc(-c6nc7ccccn7c6-c6ccccc6)cc5)cc4c(-c4ccccc4)c3cc21]

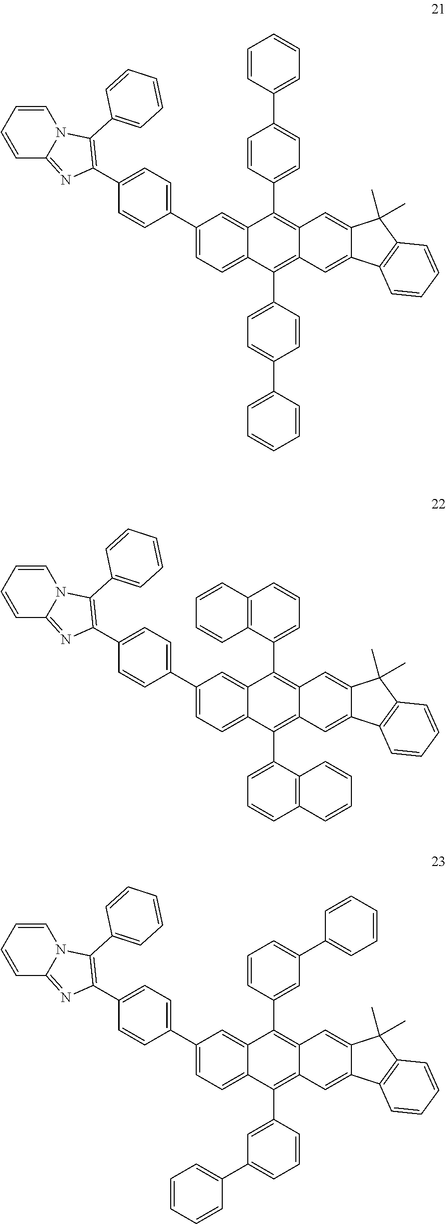 [SMILES: CC1(C)c2ccccc2-c2cc3c(-c4ccc(-c5ccccc5)cc4)c4ccc(-c5ccc(-c6nc7ccccn7c6-c6ccccc6)cc5)cc4c(-c4ccc(-c5ccccc5)cc4)c3cc21 ; CC1(C)c2ccccc2-c2cc3c(-c4cccc5ccccc45)c4ccc(-c5ccc(-c6nc7ccccn7c6-c6ccccc6)cc5)cc4c(-c4cccc5ccccc45)c3cc21 ; CC1(C)c2ccccc2-c2cc3c(-c4cccc(-c5ccccc5)c4)c4ccc(-c5ccc(-c6nc7ccccn7c6-c6ccccc6)cc5)cc4c(-c4cccc(-c5ccccc5)c4)c3cc21]

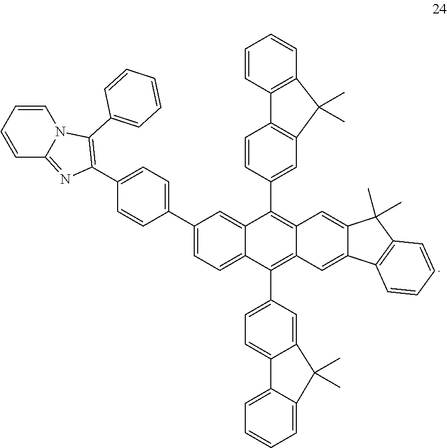 [SMILES: CC1(C)c2ccccc2-c2ccc(-c3c4ccc(-c5ccc(-c6nc7ccccn7c6-c6ccccc6)cc5)cc4c(-c4ccc5c(c4)C(C)(C)c4ccccc4-5)c4cc5c(cc34)-c3ccccc3C5(C)C)cc21]

15. An organic light-emitting diode comprising: a first electrode; a second electrode disposed opposite to the first electrode; and an organic layer disposed between the first electrode and the second electrode and comprising an emission layer, wherein the organic layer further comprises a hole transport region between the first electrode and the emission layer, and an electron transport region between the emission layer and the second electrode, wherein the organic layer comprises at least one anthracene-based compound according to claim 1.

16. The organic light emitting diode of claim 15, wherein the hole transport region further comprises at least one of a hole injection layer, a hole transport layer, a functional layer having both hole injection and hole transport capabilities, a buffer layer, and an electron blocking layer, wherein the electron transport region comprises at least one of a hole blocking layer, an electron transport layer, and an electron injection layer.

17. The organic light emitting diode of claim 15, wherein the anthracene-based compound is in the electron transport region.

18. The organic light emitting diode of claim 17, wherein the electron transport region comprises an electron transport layer and the anthracene-based compound is in the electron transport layer.

19. The organic light emitting diode of claim 15, wherein the anthracene-based compound is in the emission layer.

20. The organic light emitting diode of claim 15, wherein the hole transport region comprises a p-dopant.
